(19) United States
(12) Patent Application Publication
(10) Pub. No.: US 2022/0383657 A1
(43) Pub. Date: Dec. 1, 2022

(54) SEMICONDUCTOR DEVICE AND DETERMINATION SYSTEM

(71) Applicant: SEMICONDUCTOR ENERGY LABORATORY CO., LTD., ATSUGI-SHI, KANAGAWA-KEN (JP)

(72) Inventors: Seiko INOUE, Atsugi, Kanagawa (JP); Ayana KIMOTSUKI, Atsugi, Kanagawa (JP); Atsuya TOKINOSU, Atsugi, Kanagawa (JP)

(21) Appl. No.: 17/760,797

(22) PCT Filed: Sep. 22, 2020
(86) PCT No.: PCT/IB2020/058811

§ 371 Date: Mar. 16, 2022

(30) Foreign Application Priority Data
Oct. 4, 2019 (JP) 2019-183928

(51) Int. Cl. G06V 40/16; G06V 10/44; G06V 10/94; G06V 10/82

(52) U.S. Cl. CPC G06V 40/171; G06V 10/44; G06V 10/95; G06V 10/82

(57) ABSTRACT

Power consumption of a circuit which makes a determination is reduced. The accuracy of a system which makes a determination is improved. The safety of a target object which is monitored by a sensor element is increased. A system which easily monitors a target object is provided. A semiconductor device includes a detection circuit having a function of analyzing first data and making a first determination of selecting a first value or a second value, a first determination circuit and a second determination circuit having a function of performing feature extraction of an image, a power supply circuit, and a power management unit. The power management unit has a function of allowing a voltage to be supplied from the power supply circuit to the first determination circuit in the case where the first value is selected by the first determination. The first determination circuit has a function of analyzing the first data and making a second determination. The second determination circuit has a function of analyzing the first data and making a third determination in the case where an occurrence of an event is detected in the second determination.

### TECHNICAL FIELD

One embodiment of the present invention relates to a semiconductor device.

Note that one embodiment of the present invention is not limited to the above technical field. The technical field of the invention disclosed in this specification and the like relates to an object, a method, or a manufacturing method. Another embodiment of the present invention relates to a process, a machine, manufacture, or a composition of matter.

In this specification and the like, a semiconductor device generally means a device that can function by utilizing semiconductor characteristics. Thus, a semiconductor element such as a transistor or a diode and a circuit including a semiconductor element are semiconductor devices.

A display device, a light-emitting device, a lighting device, an electro-optical device, a communication device, an electronic device, and the like may include a semiconductor element or a semiconductor circuit. Therefore, a display device, a light-emitting device, a lighting device, an electro-optical device, an imaging device, a communication device, an electronic device, and the like are referred to as a semiconductor device in some cases.

### BACKGROUND ART

Information terminals that are easy to carry, typified by smartphones, tablet terminals, and the like, have come into widespread use. With the widespread use of information terminals, various communication standards have been established. For example, the use of an LTE-Advanced standard called the fourth-generation mobile communication system (4G) has started.

With the development of information technology such as IoT (Internet of Things), the amount of data handled in information terminals has been recently showing an increasing tendency. In addition, the transmission speed of electronic devices such as information terminals needs to be improved.

In order to be compatible with various kinds of information technology such as IoT, a new communication standard called the fifth-generation mobile communication system (5G) that achieves higher transmission speed, more simultaneous connections, and shorter delay time than 4G has been examined. Note that 5G uses communication frequencies of a 3.7 GHz band, a 4.5 GHz band, and a 28 GHz band.

A 5G compatible semiconductor device is manufactured using a semiconductor containing one kind of element such as Si as its main component or a compound semiconductor containing a plurality of kinds of elements such as Ga and As as its main components. Furthermore, an oxide semiconductor, which is one kind of metal oxide, has attracted attention.

A CAAC (c-axis aligned crystalline) structure and an nc (nanocrystalline) structure, which are neither single crystal nor amorphous, have been found in an oxide semiconductor (see Non-Patent Document 1 and Non-Patent Document 2).

Non-Patent Document 1 and Non-Patent Document 2 disclose a technique for manufacturing a transistor using an oxide semiconductor having a CAAC structure.

As techniques for reducing power consumption of semiconductor devices, power gating (PG), clock gating (CG), and voltage scaling are known, for example. Patent Document 1 discloses a technique for effectively reducing power consumption among DVFS (Dynamic Voltage and Frequency Scaling) techniques and PG techniques, for example.

### Reference

### Patent Document

[Patent Document 1] PCT International Publication No. 2009/078081

### Non-Patent Document

[Non-Patent Document 1] S. Yamazaki et al., “SID Symposium Digest of Technical Papers,” 2012, volume 43, issue 1, pp. 183-186
[Non-Patent Document 2] S. Yamazaki et al., “Japanese Journal of Applied Physics,” 2014, volume 53, Number 4S, pp. 04ED18-1-04ED18-10

### SUMMARY OF THE INVENTION

### Problems to be Solved by the Invention

An object of one embodiment of the present invention is to provide a novel semiconductor device or a method for operating the novel semiconductor device. Another object of one embodiment of the present invention is to provide a novel determination system or a method for operating the novel determination system. Another object of one embodiment of the present invention is to reduce power consumption, for example, reduce power in a resting state. Another object of one embodiment of the present invention is to shorten the time needed for a returning process from a resting state to a normal state or reduce energy needed to perform the process. Another object of one embodiment of the present invention is to reduce power consumption of a circuit which makes a determination. Another object of one embodiment of the present invention is to improve the accuracy of a system which makes a determination. Another object of one embodiment of the present invention is to increase the safety of a target object which is monitored by a sensor element. Another object of one embodiment of the present invention is to provide a system which easily monitors a target object.

Note that the descriptions of a plurality of objects do not disturb the existence of each object. One embodiment of the present invention does not necessarily achieve all these objects. Other objects will be apparent from the description of the specification, the drawings, the claims, and the like, and such objects could be objects of one embodiment of the present invention.

### Means for Solving the Problems

One embodiment of the present invention is a semiconductor device including a detection circuit, a first determination circuit, a second determination circuit, a power supply circuit, and a power management unit. The detection circuit has a function of analyzing first data and making a first determination of selecting a first value or a second value. The first determination circuit and the second determination circuit have a function of performing feature extraction of an image. The power management unit has a function of allowing a voltage to be supplied from the power supply circuit to the first determination circuit in the case where the first value is selected by the first determination. The first determination circuit has a function of analyzing the first data and making a second determination. The second determination circuit has a function of analyzing the first data and making a third determination in the case where an occurrence of an event is detected in the second determination.

In the above-described structure, the first determination circuit preferably has a function of performing contour extraction.

In the above-described structure, the first determination circuit preferably has a function of performing contour extraction, and the second determination circuit preferably has a function of executing one or more techniques selected from a deep neural network, a convolutional neural network, a recurrent neural network, an autoencoder, a deep Boltzmann machine, and a deep belief network.

In the above-described structure, the semiconductor device preferably includes an antenna and has a function of transmitting a result of the third determination by wireless communication.

In the above-described structure, the event is preferably detection of a human using the contour extraction.

In the above-described structure, the first determination circuit preferably has a function of performing face recognition of a human using the contour extraction.

One embodiment of the present invention is a determination system including an imaging device, a detection circuit, a processing device, a second determination circuit, and a power supply circuit. The processing device includes a first determination circuit, a power management unit, a processor core, and a storage circuit. The processor core has a function of giving an instruction to the first determination circuit. The storage circuit has a function of retaining data generated by the processor core. The imaging device has a function of obtaining first data. The detection circuit has a function of analyzing the first data and making a first determination of selecting a first value or a second value. The first determination circuit and the second determination circuit have a function of performing feature extraction of an image. The power management unit has a function of allowing a voltage to be supplied from the power supply circuit to the first determination circuit in the case where the first value is selected by the first determination. The first determination circuit has a function of analyzing the first data and making a second determination. The second determination circuit has a function of analyzing the first data and making a third determination in the case where an occurrence of an event is detected in the second determination. The imaging device includes a plurality of pixel circuits arranged in a matrix.

In the above-described structure, the storage circuit preferably includes a first transistor and a first capacitor, one of a source and a drain of the first transistor is preferably electrically connected to one electrode of the first capacitor, and the first transistor preferably includes an oxide semiconductor in a channel formation region.

In the above-described structure, the storage circuit preferably includes a first transistor and a first capacitor. One of a source and a drain of the first transistor is preferably electrically connected to one electrode of the first capacitor. The first transistor preferably includes a transistor including an oxide semiconductor in a channel formation region. Each of the plurality of pixel circuits preferably includes a photoelectric conversion device, a second transistor, and a second capacitor. One electrode of the photoelectric conversion device is preferably electrically connected to one of a source and a drain of the second transistor. The other of the source and the drain of the second transistor is preferably electrically connected to one electrode of the second capacitor. The second transistor preferably includes an oxide semiconductor in a channel formation region.

In the above-described structure, the first determination circuit preferably has a function of performing contour extraction.

In the above-described structure, the first determination circuit preferably has a function of performing contour extraction, and the second determination circuit preferably has a function of executing one or more techniques selected from a deep neural network, a convolutional neural network, a recurrent neural network, an autoencoder, a deep Boltzmann machine, and a deep belief network.

### Effect of the Invention

With one embodiment of the present invention, a novel semiconductor device or a method for operating the novel semiconductor device can be provided. With one embodiment of the present invention, a novel determination system or a method for operating the novel determination system can be provided. With one embodiment of the present invention, power consumption, for example, power in a resting state can be reduced. With one embodiment of the present invention, the time needed for a returning process from a resting state to a normal state can be shortened or energy needed to perform the process can be reduced. With one embodiment of the present invention, power consumption of a circuit which makes a determination can be reduced. With one embodiment of the present invention, the accuracy of a system which makes a determination can be improved. With one embodiment of the present invention, the safety of a target object which is monitored by a sensor element can be increased. With one embodiment of the present invention, a system which easily monitors a target object can be provided.

Note that the descriptions of these effects do not preclude the existence of other effects. One embodiment of the present invention does not need to have all the effects described above. In one embodiment of the present invention, other objects, effects, and novel features will be apparent from the description of the specification and the drawings.

### BRIEF DESCRIPTION OF THE DRAWINGS

FIG. 1 is a block diagram illustrating a structure example of a determination system.

FIG. 2 is a block diagram illustrating a structure example of a determination system.

FIG. 3 is a flow chart illustrating an operation example of a semiconductor device.

FIG. 4A and FIG. 4B are block diagrams illustrating a structure example of a semiconductor device.

FIG. 5A to FIG. 5D are diagrams illustrating power management operation examples of a semiconductor device.

FIG. 6 is a flow chart illustrating a power management operation example of a semiconductor device.

FIG. 7A and FIG. 7B are block diagrams illustrating a structure example of a semiconductor device.

FIG. 8 is a block diagram illustrating a structure example of a processor core.

FIG. 9 is a circuit diagram illustrating a structure example of a storage circuit.

FIG. 10 is a timing chart illustrating an operation example of a storage circuit.

FIG. 11 is a circuit diagram illustrating a structure example of a cache memory cell.

FIG. 12 is a timing chart illustrating an operation example of a memory cell.

FIG. 13A is a functional block diagram illustrating a structure example of a NOSRAM. FIG. 13B is a circuit diagram illustrating a structure example of a memory cell.

FIG. 14A is a circuit diagram illustrating a structure example of a memory cell array. FIG. 14B and FIG. 14C are circuit diagrams illustrating structure examples of a memory cell.

FIG. 15A is a circuit diagram illustrating a structure example of a memory cell of a DOSRAM.

FIG. 15B is a diagram illustrating an example of a stacked layer structure of a DOSRAM.

FIG. 16A and FIG. 16B are diagrams illustrating a structure example of a neural network.

FIG. 17 is a diagram illustrating a structure example of a semiconductor device.

FIG. 18 is a diagram illustrating a structure example of memory cells.

FIG. 19 is a diagram illustrating a structure example of an offset circuit.

FIG. 20 is a timing chart.

FIG. 21A is a block diagram illustrating an imaging device. FIG. 21B and FIG. 21C are circuit diagrams illustrating pixel circuits.

FIG. 22A is a diagram illustrating a rolling shutter operation. FIG. 22B is a diagram illustrating a global shutter operation.

FIG. 23A and FIG. 23B are timing charts illustrating operations of the pixel circuits.

FIG. 24A and FIG. 24B are circuit diagrams illustrating pixel circuits.

FIG. 25 is a circuit diagram and a block diagram illustrating a reading circuit.

FIG. 26A and FIG. 26B are cross-sectional views illustrating pixels.

FIG. 27A, FIG. 27B, and FIG. 27C are diagrams illustrating Si transistors.

FIG. 28A and FIG. 28B are cross-sectional views illustrating pixels.

FIG. 29A, FIG. 29B, FIG. 29C, and FIG. 29D are diagrams illustrating OS transistors.

FIG. 30A and FIG. 30B are cross-sectional views illustrating examples of electronic devices.

### MODE FOR CARRYING OUT THE INVENTION

Embodiments are described in detail with reference to the drawings. However, the present invention is not limited to the following description, and it is readily appreciated by those skilled in the art that modes and details can be modified in various ways without departing from the spirit and the scope of the present invention. Thus, the present invention should not be construed as being limited to the description in the following embodiments. Note that in the structures of the invention described below, the same portions or portions having similar functions are denoted by the same reference numerals in different drawings, and description thereof is not repeated.

In addition, the position, size, range, and the like of each component illustrated in the drawings and the like do not represent the actual position, size, range, and the like in some cases for easy understanding of the invention. Therefore, the disclosed invention is not necessarily limited to the position, size, range, or the like disclosed in drawings and the like. For example, in an actual manufacturing process, a resist mask or the like might be unintentionally reduced in size by treatment such as etching, which might not be reflected in the drawings for easy understanding.

Furthermore, in a top view (also referred to as a “plan view”), a perspective view, or the like, some components might not be illustrated for easy understanding of the drawings.

In addition, in this specification and the like, the terms “electrode” and “wiring” do not functionally limit these components. For example, an “electrode” is used as part of a “wiring” in some cases, and vice versa. Furthermore, the term “electrode” or “wiring” also includes the case where a plurality of “electrodes” or “wirings” are formed in an integrated manner, for example.

In this specification and the like, a “terminal” in an electric circuit refers to a portion that inputs or outputs a current, inputs or outputs a voltage, or receives or transmits a signal. Accordingly, part of a wiring or an electrode functions as a terminal in some cases.

Note that the term “over” or “under” in this specification and the like does not necessarily mean that a component is placed directly over and in contact with or directly under and in contact with another component. For example, the expression “electrode B over insulating layer A” does not necessarily mean that the electrode B is formed on and in direct contact with the insulating layer A, and does not exclude the case where another component is provided between the insulating layer A and the electrode B.

In addition, functions of a source and a drain are interchanged with each other depending on operation conditions and the like, for example, when a transistor of different polarity is employed or when the current direction is changed in a circuit operation; therefore, it is difficult to define which is the source or the drain. Thus, the terms “source” and “drain” can be interchangeably used in this specification.

In this specification and the like, the expression “electrically connected” includes the case where components are directly connected to each other and the case where components are connected through an “object having any electric function”. Here, there is no particular limitation on the “object having any electric function” as long as electric signals can be transmitted and received between components that are connected through the object. Thus, even when the expression “electrically connected” is used, there is a case where no physical connection portion is made and a wiring is just extended in an actual circuit.

Furthermore, in this specification and the like, “parallel” indicates a state where two straight lines are placed at an angle of greater than or equal to −10° and less than or equal to 10°, for example. Accordingly, the case where the angle is greater than or equal to −5° and less than or equal to 5° is also included. Moreover, “perpendicular” and “orthogonal” indicate a state where two straight lines are placed at an angle of greater than or equal to 80° and less than or equal to 100°, for example. Accordingly, the case where the angle is greater than or equal to 85° and less than or equal to 95° is also included.

In this specification and the like, the terms “identical”, “same”, “equal”, “uniform”, and the like used in describing calculation values and measurement values allow for a margin of error of ±20% unless otherwise specified.

In addition, a voltage refers to a potential difference between a certain potential and a reference potential (e.g., a ground potential or a source potential) in many cases. Therefore, the terms “voltage” and “potential” can be replaced with each other in many cases. In this specification and the like, the terms “voltage” and “potential” can be replaced with each other unless otherwise specified.

Note that a “semiconductor” has characteristics of an “insulator” when conductivity is sufficiently low, for example. Thus, a “semiconductor” can be replaced with an “insulator”. In that case, a “semiconductor” and an “insulator” cannot be strictly distinguished from each other because a border therebetween is not clear. Accordingly, a “semiconductor” and an “insulator” described in this specification can be replaced with each other in some cases.

Furthermore, a “semiconductor” has characteristics of a “conductor” when conductivity is sufficiently high, for example. Thus, a “semiconductor” can be replaced with a “conductor”. In that case, a “semiconductor” and a “conductor” cannot be strictly distinguished from each other because a border therebetween is not clear. Accordingly, a “semiconductor” and a “conductor” in this specification can be replaced with each other in some cases.

Note that ordinal numbers such as “first” and “second” in this specification and the like are used in order to avoid confusion among components and do not denote the priority or the order such as the order of steps or the stacking order. A term without an ordinal number in this specification and the like might be provided with an ordinal number in the scope of claims in order to avoid confusion among components. Furthermore, a term with an ordinal number in this specification and the like might be provided with a different ordinal number in the scope of claims. Furthermore, even when a term is provided with an ordinal number in this specification and the like, the ordinal number might be omitted in the scope of claims and the like.

Note that in this specification and the like, an “on state” of a transistor refers to a state in which a source and a drain of the transistor are electrically short-circuited (also referred to as a “conduction state”). Furthermore, an “off state” of the transistor refers to a state in which the source and the drain of the transistor are electrically disconnected (also referred to as a “non-conduction state”).

In addition, in this specification and the like, an “on-state current” sometimes refers to a current that flows between a source and a drain when a transistor is in an on state. Furthermore, an “off-state current” sometimes refers to a current that flows between a source and a drain when a transistor is in an off state.

In this specification and the like, a high power supply potential (hereinafter, also referred to as “power supply potential VDD”, “VDD”, “H potential”, or “H”) is a power supply potential higher than a low power supply potential (hereinafter, also referred to as “power supply potential VSS”, “VSS”, “L potential”, or “L”). VSS refers to a power supply potential at a potential lower than VDD. A ground potential (hereinafter, also simply referred to as “GND” or “GND potential”) can be used as VDD or VSS. For example, in the case where VDD is a ground potential, VSS is a potential lower than the ground potential, and in the case where VSS is a ground potential, VDD is a potential higher than the ground potential.

In addition, in this specification and the like, a gate refers to part or the whole of a gate electrode and a gate wiring. A gate wiring refers to a wiring for electrically connecting at least one gate electrode of a transistor to another electrode or another wiring.

Furthermore, in this specification and the like, a source refers to part or the whole of a source region, a source electrode, or a source wiring. A source region refers to a region in a semiconductor layer, where the resistivity is lower than or equal to a given value. A source electrode refers to part of a conductive layer that is connected to a source region. A source wiring refers to a wiring for electrically connecting at least one source electrode of a transistor to another electrode or another wiring.

Moreover, in this specification and the like, a drain refers to part or the whole of a drain region, a drain electrode, or a drain wiring. A drain region refers to a region in a semiconductor layer, where the resistivity is lower than or equal to a given value. A drain electrode refers to part of a conductive layer that is connected to a drain region. A drain wiring refers to a wiring for electrically connecting at least one drain electrode of a transistor to another electrode or another wiring.

In the drawings and the like, for easy understanding of the potentials of a wiring, an electrode and the like, “H” representing an H potential or “L” representing an L potential is sometimes written near the wiring, the electrode, and the like. In addition, enclosed “H” or “L” is sometimes written near a wiring, an electrode, and the like whose potential changes. Moreover, a symbol “x” is sometimes written on a transistor in an off state.

Note that a terminal may refer to a group of a plurality of terminals. Each terminal included in a group of a plurality of terminals is supplied with an independent signal, for example, and each terminal is electrically connected to one or more wirings.

A transistor includes three terminals (nodes) called a gate, a source, and a drain. The gate is a terminal that functions as a control terminal for controlling the conduction state of the transistor. Depending on the type of the transistor and the levels of potentials supplied to respective terminals (nodes), one of a pair of input/output terminals (nodes) functioning as a source and a drain serves as a source and the other serves as a drain. In general, in an n-channel transistor, a node to which a lower potential is supplied is called a source, and a node to which a higher potential is supplied is called a drain. Conversely, in a p-channel transistor, a node to which a lower potential is supplied is called a drain, and a node to which a higher potential is supplied is called a source. In this specification, two terminals (nodes) other than a gate are referred to as a first terminal (node) and a second terminal (node) in some cases.

In this specification, for easy understanding of a circuit structure and its operation, description is sometimes made on the case where one of two input/output terminals (nodes) of a transistor is fixed as a source and the other is fixed as a drain. It is needless to say that, depending on a driving method, the magnitude relationship between potentials applied to three terminals of the transistor might be changed, and the source and the drain might be interchanged with each other. Thus, in one embodiment of the present invention, the distinction between the source and the drain of the transistor is not limited to that described in this specification and the drawings.

Note that in this specification and the like, it might be possible for those skilled in the art to constitute one embodiment of the invention even when portions to which all the terminals of an active element (e.g., a transistor or a diode), a passive element (e.g., a capacitor or a resistor), or the like are connected are not specified. In other words, one embodiment of the invention can be clear even when connection portions are not specified. Furthermore, in the case where an embodiment in which a connection portion is specified is disclosed in this specification and the like, it can sometimes be judged that one embodiment of the invention in which a connection portion is not specified is disclosed in this specification and the like. In particular, in the case where the number of portions to which the terminal is connected is more than one, it is not necessary to specify the portions to which the terminal is connected. Therefore, it might be possible to constitute one embodiment of the invention by specifying only portions to which some of terminals of an active element (e.g., a transistor or a diode), a passive element (e.g., a capacitor or a resistor), or the like are connected.

Note that in this specification and the like, it might be possible for those skilled in the art to specify the invention when at least the connection portion of a circuit is specified. Alternatively, it might be possible for those skilled in the art to specify the invention when at least a function of a circuit is specified. In other words, when a function is specified, one embodiment of the present invention can be clear. Furthermore, it can be judged that one embodiment of the present invention whose function is specified is disclosed in this specification and the like. Therefore, when a connection portion of a circuit is specified, the circuit is disclosed as one embodiment of the invention even when a function is not specified, and one embodiment of the invention can be constituted. Alternatively, when a function of a circuit is specified, the circuit is disclosed as one embodiment of the invention even when a connection portion is not specified, and one embodiment of the invention can be constituted.

### Embodiment 1

In this embodiment, a semiconductor device which is one embodiment of the present invention and application examples of the semiconductor device will be described.

### <Structure Example of Semiconductor Device>

An example of a determination system of one embodiment of the present invention is described below. The determination system of one embodiment of the present invention includes a semiconductor device. The determination system of one embodiment of the present invention preferably includes an imaging device in addition to the semiconductor device. The semiconductor device of one embodiment of the present invention include a processing unit. The processing unit of one embodiment of the present invention has a function of bringing a power supply for some circuits of the processing unit into the off mode by a power gating operation. The power supply for the circuits which has been brought into the off mode can return to the on mode in accordance with an interrupt request.

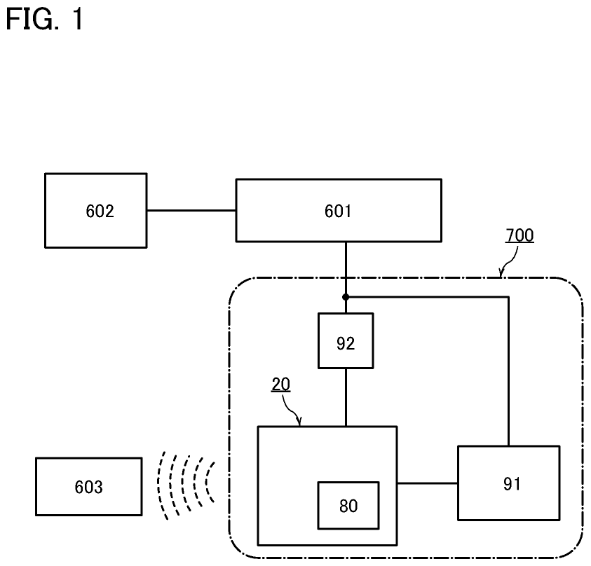

FIG. 1 illustrates a structure example of a determination system including a semiconductor device and a device such as an imaging device. A semiconductor device 700 illustrated in FIG. 1 is electrically connected to an imaging device 601. The semiconductor device 700 includes a detection circuit 92, a processing unit (PU) 20, and a determination circuit 91. The PU 20 includes a preliminary determination circuit 80. The determination circuit 91 has a function of performing an arithmetic operation using a neural network. Note that the preliminary determination circuit 80 and the determination circuit 91 are referred to as a first determination circuit and a second determination circuit, respectively, in some cases.

The imaging device 601 has a function of capturing an image from visible light. Furthermore, the imaging device 601 preferably has a function of capturing an image from infrared light.

At the time of image capturing by the imaging device 601, a subject may be irradiated with light from a prepared light source.

Furthermore, the structure example illustrated in FIG. 1 includes a display device 602. The display device 602 is electrically connected to the imaging device 601. The display device 602 has a function of displaying an image captured by the imaging device 601. The display device 602 includes a display portion and a driver circuit which controls the display portion, for example.

The structure example illustrated in FIG. 1 includes a terminal 603. The semiconductor device 700 preferably has a function of wirelessly communicating with the terminal 603. The semiconductor device 700 includes an antenna for wireless communication, for example.

The semiconductor device 700 can perform analysis in stages in the detection circuit 92, the preliminary determination circuit 80, and the determination circuit 91 in this order. Through more stages, the analysis accuracy is improved. As the analysis stages are increased, the judgement accuracy can be improved.

On the other hand, as the analysis accuracy is increased, the scale of the arithmetic circuit is increased; this might increase the power consumption of the semiconductor device 700. Therefore, in the case where the analysis is judged enough in the detection circuit 92 or the preliminary determination circuit 80, proceeding to the next stage is not necessary. With a fewer stages, the power consumption of the semiconductor device 700 can be reduced more.

The semiconductor device of one embodiment of the present invention has a function of judging whether an abnormal event has occurred. In the semiconductor device of one embodiment of the present invention, the judgement is preferably performed in stages. In an initial stage of this case, only the presence or absence of the occurrence of an event is judged and whether the event that has occurred is abnormal need not be judged.

Imaging data of the imaging device 601 is given to the detection circuit 92. The detection circuit 92 has a function of performing binary classification. More specifically, the detection circuit 92 has a function of analyzing the given data and judging whether an event has occurred. The detection circuit 92 does not judge whether the event that has occurred is abnormal, for example. The detection circuit 92 analyzes the imaging data and makes a first determination, for example. The first determination is binary classification. When exceeding a predetermined criterion, a first value is selected, and when not exceeding the predetermined criterion, a second value is selected. Here, exceeding a predetermined criterion, for example, refers to that a numerical value obtained by analyzing the imaging data and converting the result into a numerical form exceeds the predetermined criterion. Alternatively, exceeding a predetermined criterion, for example, refers to judging that an event has occurred as the result of the analysis of the imaging data. In the case where the first value is selected by the first determination made by the detection circuit 92, a signal INT is given to the PU 20, and as the next step, the imaging data is analyzed in the preliminary determination circuit 80.

Here, as an example, a case where the imaging device 601 is used to identify a suspicious person is considered. In such a case, when an image that is assumed to be an image of a person is detected in a captured image, it may be judged that “an event has occurred.” In this case, even when an event has occurred in the detection circuit 92, the person in the captured image is not necessarily a suspicious person. The event may be a simple event. For example, the event may be “detection of a movement of a subject.” Alternatively, the event may be “detection of a subject,” for example. Alternatively, the event may be “a significant change in luminance,” for example.

The detection circuit 92 performs an arithmetic operation simpler than those in the preliminary determination circuit 80 and the determination circuit 91 described later. For example, the detection circuit 92 analyzes a spatial luminance distribution of the imaging data and detects a subject. Alternatively, for example, the detection circuit 92 judges that an event has occurred in the case where the obtained data exceeds a set threshold.

The detection circuit 92 has a function of giving the signal INT to the PU 20 in response to the occurrence of an event. The signal INT is a signal for requesting interrupt processing. The power supply of a circuit, for example, a processor core, which has been brought into the off mode in the PU 20 can return to the on mode in response to an interrupt request. Then, the PU 20 executes a desired instruction, and the preliminary determination circuit 80 included in the PU 20 determines whether an abnormal event has occurred. Specifically, for example, the preliminary determination circuit 80 analyzes the imaging data and judges whether there is a suspicious person in the image.

The power consumption of the PU 20 can be substantially reduced by a power gating operation in the case where the analysis is not performed in the preliminary determination circuit 80.

The PU 20 is a circuit having a function of executing an instruction. The detailed structure of the PU 20 is described later.

Note that the preliminary determination circuit 80 may only judge whether the subject is a “human” without determining whether the subject is a suspicious person. In such a case, the determination circuit 91 determines whether the subject is a suspicious person.

For example, the preliminary determination circuit 80 performs contour extraction of a subject and detects a human. As a contour extraction technique, spatial luminance comparison can be used, for example. Specifically, analysis using HoG (Histogram of Oriented Gradient) and SVM (Support Vector Machine) can be performed, for example.

Furthermore, the preliminary determination circuit 80 may analyze a temporal change of a subject, more specifically a change per frame of a subject, for example. By analyzing the temporal change of the subject, whether the behavior of the human is suspicious may be guessed.

The preliminary determination circuit 80 preferably consumes lower power than the determination circuit 91 for the analysis. The preliminary determination circuit 80 preferably performs a smaller scale arithmetic operation than the determination circuit 91. The preliminary determination circuit 80 preferably performs an arithmetic operation in a shorter time than the time taken in the determination circuit 91.

In the case where the preliminary determination circuit 80 uses a neural network, a smaller scale arithmetic operation than the arithmetic operation of the determination circuit 91 is preferably performed. For example, in the case where both the preliminary determination circuit 80 and the determination circuit 91 perform convolutional neural network (CNN), the number of middle layers used in the preliminary determination circuit 80 is smaller than the number of middle layers used in the determination circuit 91.

In the preliminary determination circuit 80, the imaging data or the data obtained by conversion of the imaging data is analyzed and a second determination is made. When exceeding a predetermined criterion in the second determination, as the next step, the imaging data or the data obtained by conversion of the imaging data is preferably analyzed in the determination circuit 91. More specifically, for example, in the case where it is determined in the second determination that an abnormal event has occurred, in order to improve the determination accuracy, further analysis is preferably performed and whether an abnormal event has occurred is preferably determined in the determination circuit 91. The determination circuit 91 has a function of performing an arithmetic operation using a neural network, for example.

When more detailed analysis is performed in the determination circuit 91 after the determination is made in the preliminary determination circuit 80, the determination accuracy can be improved. Furthermore, in the case where the preliminary determination circuit 80 makes a determination in advance and judges that no abnormal event has occurred, the arithmetic operation need not be performed in the determination circuit 91; accordingly, the power consumption of the semiconductor device 700 can be reduced.

The determination circuit 91 can perform a higher accuracy arithmetic operation than the preliminary determination circuit 80. The determination circuit 91 preferably performs analysis using artificial intelligence (AI).

The determination circuit 91 preferably executes one technique or a combination of two or more techniques selected from a deep neural network (DNN), a convolutional neural network (CNN), a recurrent neural network (RNN), an autoencoder, a deep Boltzmann machine (DBM), a deep belief network (DBN), and the like and analyzes the imaging data. More specifically, in the determination circuit 91, a CNN can be used for feature extraction of an image.

In the determination circuit 91, before feature extraction of an image using a CNN or the like, processing for increasing the image resolution, colorization processing for a black and white image, or the like may be performed. As a colorization technique, a technique called a generative adversarial network (GAN) may be used, for example.

In the case where the determination circuit 91 determines that an abnormal event has occurred, the semiconductor device 700 gives a signal indicating an abnormality to the terminal 603 by wireless communication. Furthermore, the image data in which the occurrence of an abnormal event has been determined may be transmitted together with the signal indicating an abnormality. At this time, the image data subjected to processing for increasing the resolution or colorization processing may be transmitted.

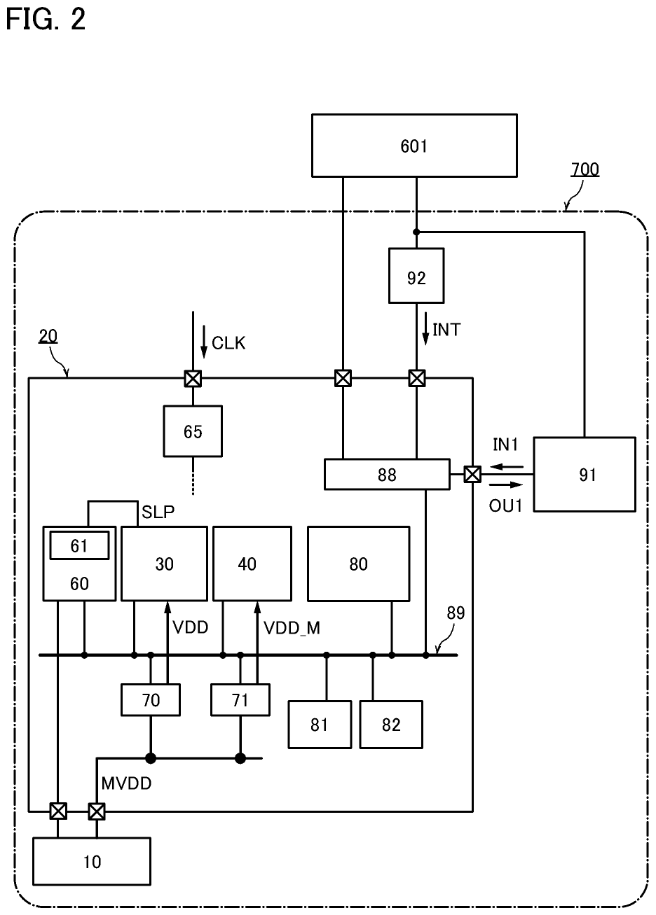

A structure example of the semiconductor device is described with reference to FIG. 2. The semiconductor device 700 illustrated in FIG. 1 includes a power supply circuit 10, the PU 20, the determination circuit 91, and the detection circuit 92. The semiconductor device 700 is electrically connected to the imaging device 601.

The PU 20 is a circuit having a function of executing an instruction. The PU 20 includes a plurality of functional circuits integrated over one chip. The PU 20 includes a processor core 30, a power management unit (PMU) 60, a clock control circuit 65, a power switch (PSW) 70, the preliminary determination circuit 80, a memory 81, a circuit 82, an interface 88, and a bus line 89.

Furthermore, the PU 20 may include a cache 40 and a power switch (PSW) 71. The details of the cache 40 and the PSW 71 are described later.

The processor core 30, the PMU 60, the cache 40, the PSW 70, the PSW 71, the preliminary determination circuit 80, the memory 81, the circuit 82, and the interface 88 are electrically connected to each other through the bus line 89. Each of the circuits can transmit and receive signals through the bus line 89. The processor core 30 has a function of giving an instruction to the preliminary determination circuit 80, for example.

The memory 81 has a function of retaining the imaging data given from the imaging device 601 to the PU 20. As the memory 81, a memory including OS transistors described later may be used.

The interface 88 has a function of transmitting and receiving signals to/from a device outside the PU 20.

The interface 88 has a function of giving the interrupt signal INT, which is given from the detection circuit 92, to the processor core 30 and the PMU 60 through the bus line 89.

Furthermore, the interface 88 has a function of receiving a signal from the processor core 30 or the like through the bus line 89 and giving a signal OU1 as a control signal to the determination circuit 91 on the basis of the received signal. Moreover, the determination circuit 91 has a function of giving a signal IN1 as a determination result to the interface 88.

The circuit 82 includes an analog-digital converter circuit (hereinafter, an AD converter circuit), for example. The circuit 82 may include a circuit for performing wireless communication. As the circuit for performing wireless communication, a modulation circuit, a demodulation circuit, and the like can be given, for example.

FIG. 2 illustrates an example where the power supply circuit 10 is provided over a chip different from a chip over which the PU 20 is provided. The power supply circuit 10 has a function of inputting a power supply potential MVDD to the PU 20. A reference clock signal CLK is given from the outside to the clock control circuit 65. The clock control circuit 65 has a function of giving a clock signal to each of the circuits included in the PU 20. Furthermore, by inputting the signal INT, which is the interrupt signal for requesting interrupt processing, to the interface 88 from the outside, a restoration sequence can be executed. The PMU 60 has a function of generating a control signal and giving the signal to the power supply circuit 10.

In the semiconductor device of one embodiment of the present invention, the number of bits the processing unit can handle in an arithmetic circuit or the like can be 8 bits, 16 bits, 32 bits, or 64 bits, for example.

The reference clock signal CLK is input to the clock control circuit 65, and the clock control circuit 65 has a function of generating and outputting a gated clock signal.

The imaging data captured by the imaging device 601 is, for example, analog data. In the case where the imaging device 601 includes an AD converter circuit, the analog data captured by the imaging device 601 is preferably given to the semiconductor device 700 after being converted by the AD converter circuit.

The analog data captured by the imaging device 601 may be given to the semiconductor device 700 without being converted into digital data. In that case, the semiconductor device 700 may conduct data conversion with the AD converter circuit included in the circuit 82, for example.

For example, digital data obtained by conversion by the AD converter circuit is given to the detection circuit 92. Alternatively, the detection circuit 92 may have a function of analyzing analog data.

For example, digital data obtained by conversion by the AD converter circuit is given to the preliminary determination circuit 80. Alternatively, the preliminary determination circuit 80 may have a function of analyzing analog data.

Furthermore, for example, the digital data obtained by conversion by the AD converter circuit is given to the determination circuit 91. Alternatively, the determination circuit 91 may have a function of analyzing analog data.

### <Operation Example of Semiconductor Device>

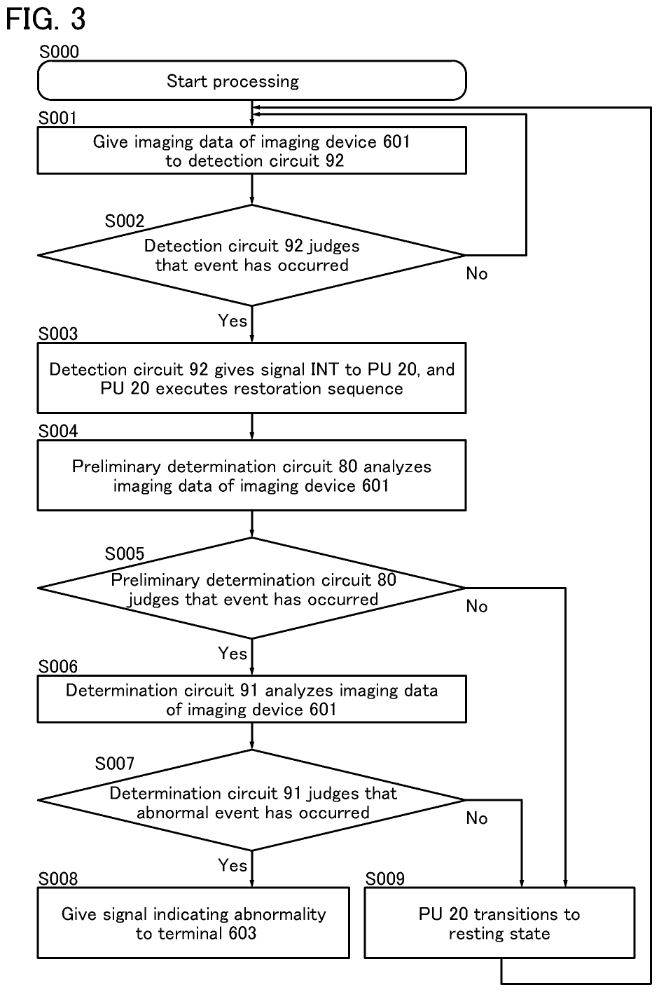

An operation example of the semiconductor device of one embodiment of the present invention is described with reference to a flow chart in FIG. 3.

In Step S000, processing starts.

In Step S001, the imaging data of the imaging device 601 is given to the detection circuit 92. The imaging data is, for example, a still image or a moving image of a monitoring place.

In Step S002, the detection circuit 92 analyzes the imaging data. In the case where the detection circuit 92 judges that “an event has occurred” as the result of the analysis, the process goes to Step S003. In the case where the detection circuit 92 judges that “no event has occurred,” the process goes back to Step S001. Here, the occurrence of an event refers to detection of a “human” or the occurrence of a more simple event. The simple event refers to “detection of a movement of a subject,” “detection of a subject,” “a significant change in luminance,” or the like, described above, for example.

In Step S003, the signal INT is given from the detection circuit 92 to the PU 20, and the PU 20 executes a restoration sequence. After the restoration of the PU 20, the imaging data of the imaging device 601 or the data obtained by subjecting the imaging data of the imaging device 601 to processing is given to the PU 20. The processing which the imaging data is subjected to refers to one or a combination of a plurality of processings selected from amplification of a signal, signal conversion processing from analog to digital form, conversion processing from digital to analog form, signal compression, signal restoration, and the like, for example.

In Step S004, the preliminary determination circuit 80 included in the PU 20 analyzes the imaging data. An example of the imaging data analysis refers to detection of a “human” by contour extraction using HoG and SVM.

In Step S005, in the case where the preliminary determination circuit 80 judges that “an event has occurred” as the result of the analysis in Step S004, the process goes to Step S006. In the case where the preliminary determination circuit 80 judges that “no event has occurred,” the process goes to Step S009.

Here, the preliminary determination circuit 80 may judge not only the presence or absence of the occurrence of an event but also whether the event that has occurred is abnormal. For example, after a “human” is detected by contour extraction, face recognition of the detected “human” may be performed.

In Step S009, the PU 20 transitions to a resting state. Then, the process goes back to Step S001.

In Step S006, the imaging data of the imaging device 601 or the data obtained by subjecting the imaging data of the imaging device 601 to processing is given to the determination circuit 91, and the determination circuit 91 analyzes the imaging data. Specifically, for example, feature extraction using a CNN is performed to recognize the face of a “human.” Then, the recognized face is compared with a database and it is judged whether the recognized person is a dangerous character. The database is included in the PU 20 or the determination circuit 91, for example. Alternatively, the database may be included in an external server. For example, it is preferable that the external server and the PU 20 wirelessly communicate with each other so that data transfer can be performed between the server and the PU 20.

In Step S007, in the case where the determination circuit 91 judges that “an abnormal event has occurred” as the result of the analysis in Step S006, the process goes to Step S008. In the case where the determination circuit 91 judges that “no abnormal event has occurred,” the process goes to Step S009. Here, the occurrence of an abnormal event refers to detection of an unexpected subject, for example. Alternatively, the occurrence of an abnormal event refers to detection of an object, subject, human, or the like which matches or highly possibly matches a previously registered database, for example. The abnormal event refers to detection of an object, subject, human, or the like which is judged dangerous, for example. Alternatively, the abnormal event refers to that the determination circuit 91 judges that the face of the recognized “human” highly possibly matches a dangerous character as the result of the analysis of the imaging data, for example.

In Step S008, the semiconductor device 700 gives a signal indicating an abnormality to the terminal 603. Here, the semiconductor device 700 may give to the terminal 603 an image of the face of the “human” which, according to the judgement, highly possibly matches a dangerous character, in addition to the signal indicating an abnormality.

The processor core, a storage circuit, and the cache are described in detail below.

### <Processor Core 30 and Storage Circuit 31>

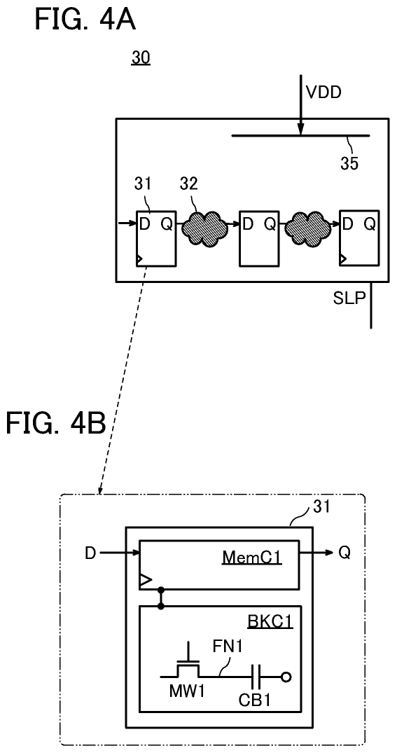

FIG. 4A illustrates an example of the structure of the processor core 30. The processor core 30 is a circuit capable of processing an instruction and can be referred to as an arithmetic processing circuit. The processor core 30 includes a storage circuit 31, a plurality of combinational circuits 32, and the like, and a variety of functional circuits are formed using these circuits. For example, the storage circuit 31 is included in a register. In FIG. 4A and the like, a signal input to the storage circuit 31 is denoted by a signal D, and a signal output from the storage circuit 31 is denoted by a signal Q.

As illustrated in FIG. 4B, the storage circuit 31 includes a circuit MemC1 and a circuit BKC1. The circuit MemC1 has a function of retaining data generated in the processor core 30, and can be formed using a flip-flop circuit (FF) or a latch circuit, for example. The circuit BKC1 can function as a backup circuit of the circuit MemC1, and can retain data for a long time even when power supply is stopped or supply of a clock signal is stopped. The use of the storage circuit 31 enables power gating of the processor core 30. This is because the state of the processor core 30 at the time of power-off can be retained by saving data of the circuit MemC1 to the circuit BKC1 in the storage circuit 31 before power-off. When the power supply is restarted, data retained in the circuit BKC1 is written to the circuit MemC1; thus, the state of the processor core 30 at the time of power-off can be restored. Consequently, the PU 20 can perform normal processing immediately after the power supply is restarted.

The circuit BKC1 includes at least a retention circuit including one transistor (MW1) and one capacitor (CB1). The retention circuit illustrated in FIG. 4B has a circuit structure similar to a 1T1C (one transistor and one capacitor) memory cell structure of a standard DRAM (dynamic random access memory), and can perform write and read operations as in the standard DRAM. By control of the conduction state of the transistor MW1, charging and discharging of the capacitor CB1 are controlled. When the transistor MW1 is turned off, a node FN1 is brought into an electrically floating state. Fluctuation in the potential of the node FN1 can be inhibited by a significant reduction in the drain current of the transistor MW1 in an off state (off-state current); thus, the data retention time of the circuit BKC1 can be made longer. The data retention time of the circuit BKC1 is determined by the leakage current of the transistor MW1, the capacitance of the capacitor CB1, and the like. The use of the transistor MW1 having an extremely low off-state current eliminates the necessity of refreshing the circuit BKC1 while the PU 20 operates. Thus, the circuit BKC1 can be used as a nonvolatile storage circuit.

A transistor including an oxide semiconductor (OS), which is one kind of metal oxide, in a semiconductor layer where a channel is formed (such a transistor is also referred to as an “OS transistor” or “OS-FET”) is preferably used as the transistor MW1. An oxide semiconductor has a band gap of 2 eV or more and thus has an extremely low off-state current. In an OS transistor, a normalized off-state current per micrometer of channel width at a source-drain voltage of 10 V can be less than or equal to 10×10⁻²¹ A (10 zA (zeptoamperes)). When the transistor MW1 is an OS transistor, the circuit BKC1 can substantially function as a nonvolatile storage circuit while the PU 20 operates.

An oxide semiconductor film used for a semiconductor layer where a channel is formed may be formed of a single oxide semiconductor film or stacked oxide semiconductor films. An oxide semiconductor included in the semiconductor layer where a channel is formed is preferably an oxide containing one or more elements selected from In, Ga, Sn, and Zn. As such an oxide, an In—Sn—Ga—Zn oxide, an In—Ga—Zn oxide, an In—Sn—Zn oxide, an In—Al—Zn oxide, a Sn—Ga—Zn oxide, an Al—Ga—Zn oxide, a Sn—Al—Zn oxide, an In—Zn oxide, a Sn—Zn oxide, an Al—Zn oxide, a Zn—Mg oxide, a Sn—Mg oxide, an In—Mg oxide, an In—Ga oxide, an indium oxide, a tin oxide, a zinc oxide, or the like can be used.

As the oxide semiconductor, a metal oxide such as an In-M-Zn oxide (the element M is one or more of aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) can be used.

Data is written with voltage in the circuit BKC1; thus, the write power of the circuit BKC1 can be lower than that of an MRAM (magnetoresistive RAM) in which writing is performed with current. Furthermore, unlike in a flash memory, the number of data rewriting times is not limited because data is retained by the load capacitance of the node FN1.

In the circuit BKC1, energy required for data writing corresponds to energy required for charging and discharging of charge in the capacitor CB1. By contrast, in a storage circuit including a two-terminal storage element such as an MRAM, energy required for data writing corresponds to energy consumed when a current flows to the storage element. In the MRAM, energy required for data writing is high because a current continuously flows during a data writing period. As compared with such an MRAM, the circuit BKC1 can reduce energy consumed by data writing. Thus, as compared with a storage circuit in which a backup circuit is formed using an MRAM, the storage circuit 31 can frequently perform voltage scaling and power gating for reducing consumed energy, which leads to a reduction in the power consumption of the PU 20.

### <Power Management>

The PMU 60 has a function of controlling a power gating operation, a clock gating operation, a voltage scaling operation, and the like. Specifically, the PMU 60 has a function of controlling the power supply circuit 10, a function of controlling the storage circuit 31, a function of controlling the clock control circuit 65, and a function of controlling the PSW 70. Thus, the PMU 60 has a function of generating control signals for controlling these circuits (the power supply circuit 10, the storage circuit 31, the clock control circuit 65, and the PSW 70). The PMU 60 includes a circuit 61. The circuit 61 has a function of measuring time. The PMU 60 has a function of performing power management on the basis of data on time obtained by the circuit 61.

The PSW 70 has a function of controlling supply of a power supply potential MVDD to the PU 20 in response to a control signal of the PMU 60. Here, a power supply potential supplied to the PU 20 through the PSW 70 is referred to as the power supply potential VDD. The processor core 30 may include a plurality of power domains. In that case, supply of power to the plurality of power domains may be controlled independently by the PSW 70. In addition, the processor core 30 may include a power domain that does not require power gating. In that case, a power supply potential may be supplied to this power domain without through the PSW 70.

The clock control circuit 65 has a function of stopping supply of a clock signal to the processor core 30 in response to a control signal of the PMU 60. The power supply circuit 10 has a function of changing the magnitude of the power supply potential VDD in response to a control signal of the PMU 60.

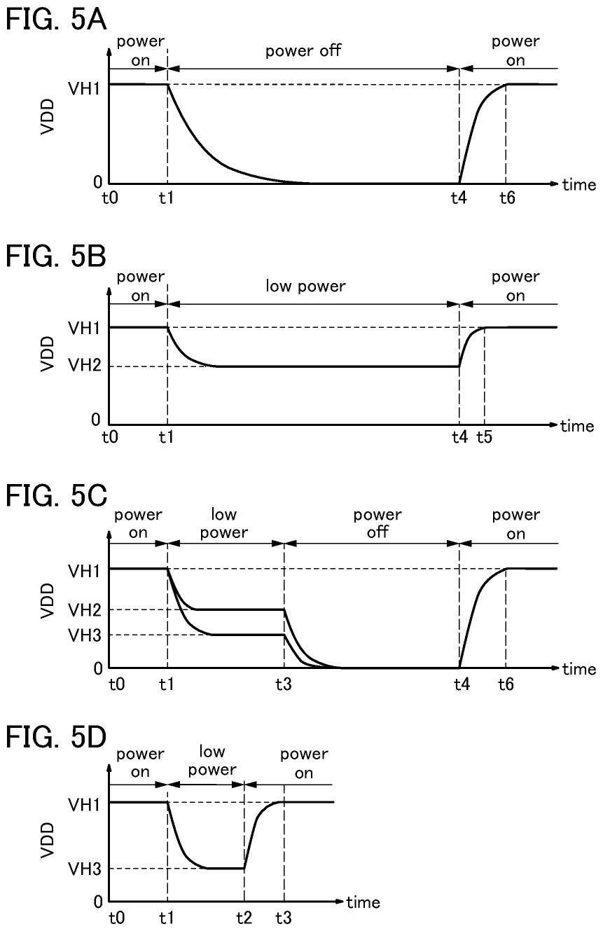

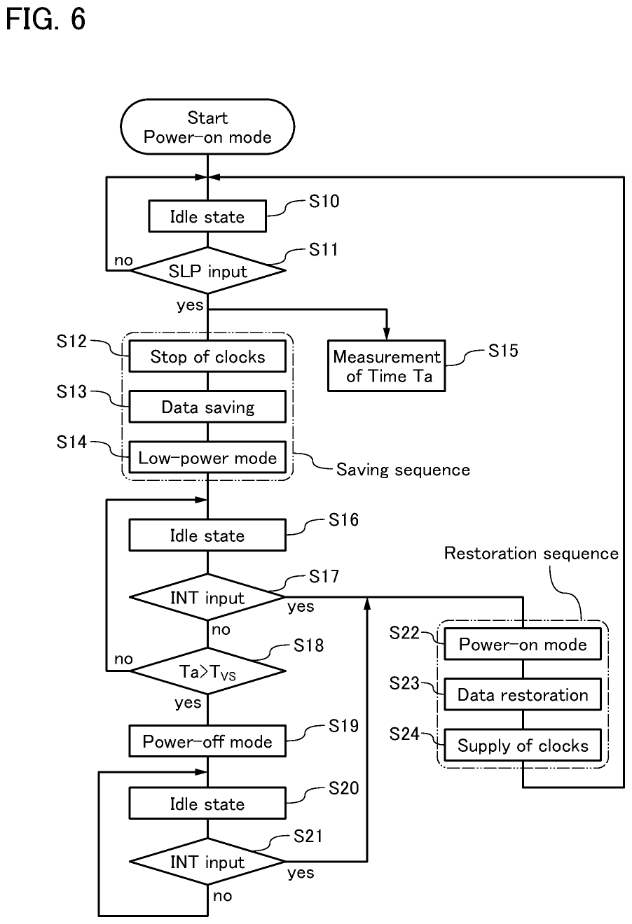

A signal SLP output from the processor core 30 to the PMU 60 is a trigger signal for making the processor core 30 transition to a resting state. When the signal SLP is input to the PMU 60, the PMU 60 generates a control signal for transition to a resting state and outputs the control signal to a functional circuit to be controlled. The power supply circuit 10 makes the power supply potential MVDD lower than that in a normal operation in response to a control signal of the PMU 60. After the processor core 30 is in the resting state for a certain period of time, the PMU 60 controls the PSW 70 and stops power supply to the processor core 30. When the processor core 30 transitions from a normal state to the resting state, the PMU 60 performs a voltage scaling operation for lowering the power supply potential VDD of the processor core 30. When the period of the resting state exceeds the set time, the PMU 60 performs a power gating operation for stopping supply of the power supply potential VDD to the processor core 30 in order to further reduce the power consumption of the processor core 30. Power management of the semiconductor device illustrated in FIG. 2 is described below with reference to FIG. 5 and FIG. 6.

FIG. 5 schematically shows changes in the potential of a power supply line 35. The power supply potential VDD is supplied to the power supply line 35 through the PSW 70. The horizontal axis in each diagram shows the time elapsing between transition from the normal state to the resting state, and t0, t1, and the like each represent time. The vertical axis in each diagram shows the potential of the power supply line. FIG. 5A shows an example in which only power gating is executed in the resting state, and FIG. 5B shows an example in which only voltage scaling is executed in the resting state. FIG. 5C and FIG. 5D each show an example in which voltage scaling and power gating are executed. In the normal state, the magnitude of the power supply potential MVDD supplied from the power supply circuit 10 is VH1.

In the following description, the power mode of the PU 20 is divided into three modes: a power-on mode, a power-off mode, and a low-power mode. The power-on mode is a mode in which the power supply potential VDD that enables normal processing is supplied to the PU 20. The power-off mode is a mode in which the supply of the power supply potential VDD is stopped by the PSW 70. The low-power mode is a mode in which the power supply potential VDD lower than that in the power-on mode is supplied.

The example in FIG. 5A is described. At the time t0, processing for transition to the resting state is started in the processor core 30. For example, backup of the storage circuit 31 is performed. The PMU 60 controls the PSW 70 and stops supply of power to the processor core 30 at the time t1. A power supply line 35 is self-discharged and its potential is decreased to 0 V. Consequently, a leakage current of the processor core 30 in the resting state can be significantly lowered, so that power consumption in the resting state (hereinafter, referred to as standby power in some cases) can be reduced. In the case where the processor core 30 returns to the normal state in response to an interrupt request or the like from the outside, the PMU 60 controls the PSW 70 and restarts the supply of the power supply potential VDD. Here, at time t4, the supply of the power supply potential VDD is restarted. The potential of the power supply line 35 increases and becomes VH1 at time t6.

In the case of the example in FIG. 5B, voltage scaling is performed; thus, at the time t1, the PMU 60 controls the power supply circuit 10 and lowers the potential of the power supply potential MVDD to VH2. The potential of the power supply line 35 eventually becomes VH2. At the time t4, when the power supply potential MVDD returns from VH2 to VH1, the potential of the power supply line 35 increases and becomes VH1 at time t5.

In the case of the example in FIG. 5A, time taken for the return from the resting state to the normal state (overhead time) is time taken to increase the potential of the power supply line 35 from 0 V to VH1, and an energy overhead required for the return is energy required to charge the load capacitance of the power supply line 35 from 0 V to VH1. When the period of the power-off mode (t1 to t4) is sufficiently long, power gating is effective in reducing standby power of the PU 20. By contrast, when the period (t1 to t4) is short, power required for the return to the normal state is higher than power reduced by power-off; therefore, the effect of power gating cannot be obtained.

In the example of voltage scaling shown in FIG. 5B, the potential of the power supply line 35 is VH2 in the resting state; thus, the amount of standby power reduction is smaller than that in the example of power gating in FIG. 5A. In the example of FIG. 5B, fluctuation in the potential of the power supply line 35 is small; therefore, time taken for the return to the normal state is shorter and energy required for the return is lower than those in the example of FIG. 5A. Accordingly, the semiconductor device illustrated in FIG. 2 can perform power management in which power gating and voltage scaling are combined to efficiently reduce the standby power of the PU 20. FIG. 5C and FIG. 5D each show a power management example.

As shown in FIG. 5C, first, a voltage scaling operation is performed in the resting state and the mode transitions from the power-on mode to the low-power mode. As in FIG. 5B, at the time t1, the PMU 60 controls the power supply circuit 10 and lowers the potential of the power supply potential MVDD to VH2; thus, the potential of the power supply line 35 eventually becomes VH2. After a certain period of time from transition to the low-power mode (t1 to t3), the PMU 60 controls the PSW 70 and transfers the mode to the power-off mode. In the period (t3 to t4), power reduced by powering off the PU 20 by power gating, which includes power consumed by returning to the normal state, is higher than power reduced by supplying VH2 to the PU 20.

For example, the potential VH2 is a power supply potential high enough to retain data in the circuit MemC1 of the storage circuit 31, and a potential VH3 is a potential at which data of the circuit MemC1 is lost. In the PU 20 of FIG. 2A, the circuit BKC1 can retain data even while power supply is stopped. When data of the storage circuit 31 is saved to the circuit BKC1 in the period (t0 to t1), VDD can be lowered to the potential VH3 at which data of the circuit MemC1 is lost in the low-power mode. Thus, the standby power of the PU 20 can be further reduced.

The PMU 60 has a function of returning the PU 20 to the normal state in response to an interrupt request or the like. The PMU 60 controls the power supply circuit 10 to increase the magnitude of MVDD to VH1 and controls the PSW 70 to restart the supply of VDD from the PU 20. After the time t4, the power-on mode continues. In the case where the potential of the power supply line 35 is stabilized at the time t6, the PU 20 can perform a normal operation after the time t6.

FIG. 5D shows an example in which an interrupt request for the return to a normal operation is input before the time t3. After the time t2, the power-on mode continues. At the time t2, the PMU 60 controls the power supply circuit 10 to change the magnitude of MVDD to the potential VH1 in the power-on mode. At the time t3, the potential of the power supply line 35 increases to VH1.

As shown in FIG. 5C and FIG. 5D, time required to restore the potential of the power supply line 35 to VH1 in the resting state is longer when the mode returns from the power-off mode to the power-on mode than when the mode returns from the low-power mode to the power-on mode. Thus, the PMU 60 has a function of adjusting timing of returning the processor core 30 from the resting state to the normal state depending on the power mode. Accordingly, the processor core 30 can return from the resting state to the normal state in the minimum time.

In the resting state, transition time from the low-power mode to the power-off mode can be measured by the circuit 61 provided in the PMU 60. When the signal SLP is input from the PU 20, the PMU 60 starts time measurement in the circuit 61. After a certain period of time from transition to the low-power mode, the PMU 60 transitions to the power-off mode. The PSW 70 is turned off by a control signal of the PMU 60, and the supply of VDD is stopped. In this manner, the PMU 60 can transition from the low-power mode to the power-off mode in response to an interrupt request based on measurement data of the circuit 61. A power management operation example of the PMU 60 is described below with reference to FIG. 6.

The PU 20 performs a normal operation. The power mode is a power-on mode and the PMU 60 is in an idle state (Step S10). The PMU 60 is in the idle state until the signal SLP is input, and a saving sequence is executed with input of the signal SLP as a trigger (Step S11). In the saving sequence example of FIG. 6, first, the PMU 60 outputs a control signal to the clock control circuit 65 and stops output of a clock signal (Step S12). Next, a control signal for data saving is output to the storage circuit 31 (Step S13). In the storage circuit 31, data retained in the circuit MemC1 is saved to the circuit BKC1 in response to a control signal of the PMU 60. Finally, the PMU 60 controls the power supply circuit 10 to lower MVDD. Through these operations, the power mode transitions to the low-power mode (Step S14). When the signal SLP is input, the PMU 60 controls the circuit 61 included therein and measures time Ta in the low-power mode (Step S15). Timing of operating the circuit 61 may be any timing as long as the saving sequence is executed; for example, the circuit 61 may operate when the signal SLP is input, when a control signal is output to the clock control circuit 65, when data saving is started, when data saving is terminated, or when a control signal is output to the power supply circuit 10.

After the saving sequence is executed, the PMU 60 is set in an idle state (Step S16), and monitors input of the signal INT and the time Ta that is measurement time of the clock control circuit 65. When the signal INT is input, the sequence transitions to a restoration sequence (Step S17). Whether the time Ta exceeds set time T_{νs} is determined (Step S18). When the time Ta exceeds the time T_{νs}, the PMU 60 executes a controls so that the power mode transitions to the power-off mode (Step S19). When the time Ta does not exceed the time T_{νs}, the PMU 60 remains in the idle state (Step S16). The time T_{νs} is set such that the standby power of the processor core 30 in the power-off mode can be lower than that in the low-power mode.

In Step S19, the PMU 60 outputs, to the PSW 70, a control signal for stopping supply of power to the processor core 30. After the mode is set to the power-off mode, the PMU 60 is in the idle state again (Step S20), and input of the signal INT is monitored (Step S21). When the signal INT is input, the PMU 60 executes the restoration sequence.

In the restoration sequence, first, the PMU 60 transitions from the power-off mode to the power-on mode (Step S22). The PMU 60 controls the power supply circuit 10 to output a power supply potential in a normal operation. In addition, the PMU 60 controls the PSW 70 to restart the supply of VDD to the processor core 30. Next, a control signal is output to the storage circuit 31 and data of the storage circuit 31 is restored (Step S23). In the storage circuit 31, data retained in the circuit BKC1 is restored to the circuit MemC1 in response to a control signal of the PMU 60. The PMU 60 outputs a control signal for outputting a clock signal to the clock control circuit 65 (Step S24). The clock control circuit 65 restarts the output of a clock signal in response to a control signal of the PMU 60.

As compared with the case where the restoration sequence is executed on the basis of the determination in Step S21, the potential of the power supply line 35 can be quickly stabilized in the case where the restoration sequence is executed on the basis of the determination in Step S17 because the power mode returns from the low-power mode to the power-on mode. Thus, in the PMU 60, timing of executing Step S23 of the case of the transition from Step S17 to the restoration sequence is faster than that of the case of the transition from Step S21 to the restoration sequence. Consequently, time taken to return the processor core 30 from the resting state to the normal state can be shortened.

As described above, in power management of the semiconductor device illustrated in FIG. 2, when the PU 20 is set in the resting state, first, time and energy overheads due to the return from the resting state to the normal state are suppressed while a leakage current is reduced by lowering a power supply potential supplied to the processor core 30 with a voltage scaling operation. When the PU 20 is in the resting state for a certain period of time, a power gating operation is performed to reduce the leakage current of the processor core 30 as much as possible. Thus, the power consumption of the PU 20 in the resting state can be reduced without a decrease in the processing performance of the PU 20.

Furthermore, the processing unit (PU) 20 may include the cache 40 and a power switch (PSW) 71. The cache 40 can perform power gating and voltage scaling, and the power mode of the cache 40 changes along with the power mode of the PU 20. The PSW 71 controls supply of the power supply potential MVDD to the cache 40 and is controlled by the PMU 60. Here, a power supply potential input to the cache 40 through the PSW 71 is VDD_M. A control signal from the PMU 60 and a gated clock signal from the clock control circuit 65 are input to the cache 40, like the processor core 30.

### <Cache 40>

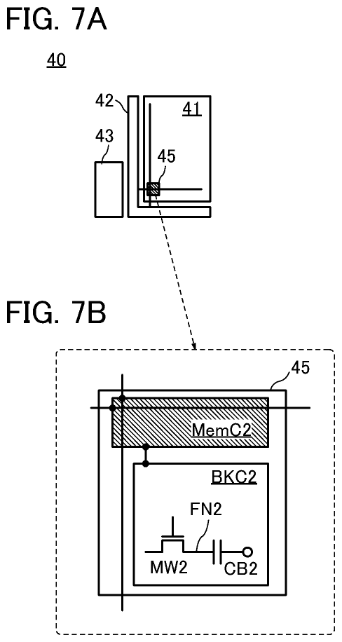

The cache 40 is a storage device having a function of temporarily storing frequently used data. The cache 40 illustrated in FIG. 7A includes a memory array 41, a peripheral circuit 42, and a control circuit 43. The memory array 41 includes a plurality of memory cells 45. The control circuit 43 controls the operation of the cache 40 in response to a request from the processor core 30. For example, a writing operation and a reading operation of the memory array 41 are controlled. The peripheral circuit 42 has a function of generating a signal for driving the memory array 41 in response to a control signal from the control circuit 43. The memory array 41 includes the memory cells 45 for retaining data.

As shown in FIG. 7B, the memory cells 45 each include a circuit MemC2 and a circuit BKC2. The circuit MemC2 is a memory cell to be accessed in a normal operation. For example, an SRAM (static random access memory) cell is used. The circuit BKC2 can function as a backup circuit of the circuit MemC2, and can retain data for a long time even while power supply is stopped or supply of a clock signal is stopped. When such memory cells 45 are provided, power gating of the cache 40 can be performed. Before the power supply is stopped, data of the circuit MemC2 is saved to BKC2 in each of the memory cells 45. After the power supply is restarted, data retained in the circuit BKC2 is restored to the circuit MemC2, so that the PU 20 can quickly return to the state before the power supply is stopped.

Like the circuit BKC1, the circuit BKC2 in each of the memory cells 45 includes at least a retention circuit including one transistor (MW2) and one capacitor (CB2). In other words, the circuit BKC2 also includes a retention circuit having a structure similar to that of a 1T1C memory cell of a standard DRAM. The transistor MW2 has an extremely low off-state current. Like the transistor MW1, an OS transistor is used as the transistor MW2. Such a structure can suppress fluctuation in the potential of a node FN2 that is electrically floating also in the circuit BKC2; thus, the circuit BKC2 can retain data for a long time. The data retention time of the circuit BKC2 is determined by the leakage current of the transistor MW2, the capacitance of the capacitor CB2, and the like. When the transistor MW2 has an extremely low off-state current, the circuit BKC2 can be used as a nonvolatile storage circuit that does not need a refresh operation.

In the case where the PU 20 includes the cache 40, in Step S13 in FIG. 6, a data saving operation of the storage circuit 31 and the cache 40 is performed. In Step S19, the PSW 70 and the PSW 71 are controlled to stop supply of power to the processor core 30 and the cache 40. In Step S22, the PSW 70 and the PSW 71 are controlled to restart the supply of power to the processor core 30 and the cache 40. In Step S23, a data restoration operation of the storage circuit 31 and the cache 40 is performed.

### <<Processor Core Structure Example>>

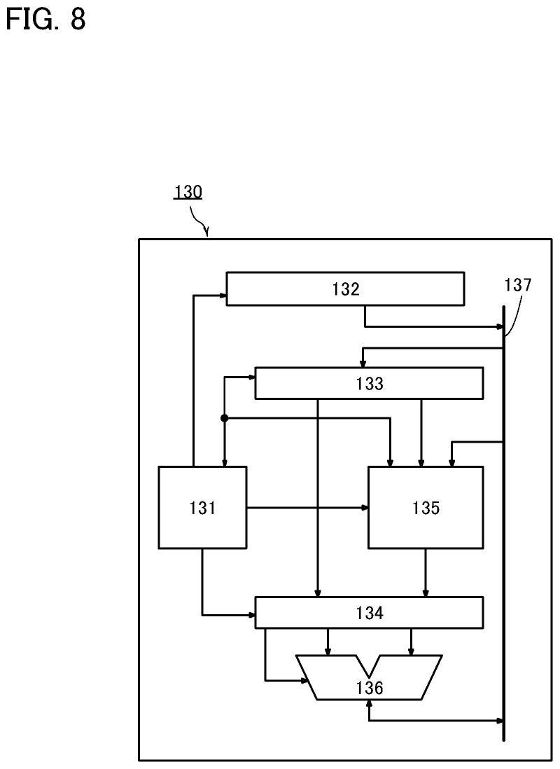

FIG. 8 shows a processor core structure example. A processor core 130 shown in FIG. 8 includes a control device 131, a program counter 132, a pipeline register 133, a pipeline register 134, a register file 135, an arithmetic logic unit (ALU) 136, and a data bus 137. Data is transmitted between the processor core 130 and a peripheral circuit such as a PMU or a cache through the data bus 137.

The control device 131 has a function of decoding and executing instructions contained in a program such as input applications by controlling the overall operations of the program counter 132, the pipeline register 133, the pipeline register 134, the register file 135, the ALU 136, and the data bus 137. The ALU 136 has a function of performing a variety of arithmetic operations such as four arithmetic operations and logic operations. The program counter 132 is a register having a function of storing the address of an instruction to be executed next.

The pipeline register 133 has a function of temporarily storing instruction data. The register file 135 includes a plurality of registers including a general-purpose register and can store data read out from a main memory, data obtained as a result of arithmetic operations in the ALU 136, or the like. The pipeline register 134 has a function of temporarily storing data used for arithmetic operations in the ALU 136, data obtained as a result of arithmetic operations in the ALU 136, or the like.

The storage circuit 31 in FIG. 4B is used as the register included in the processor core 130.

### <Storage Circuit Structure Example>

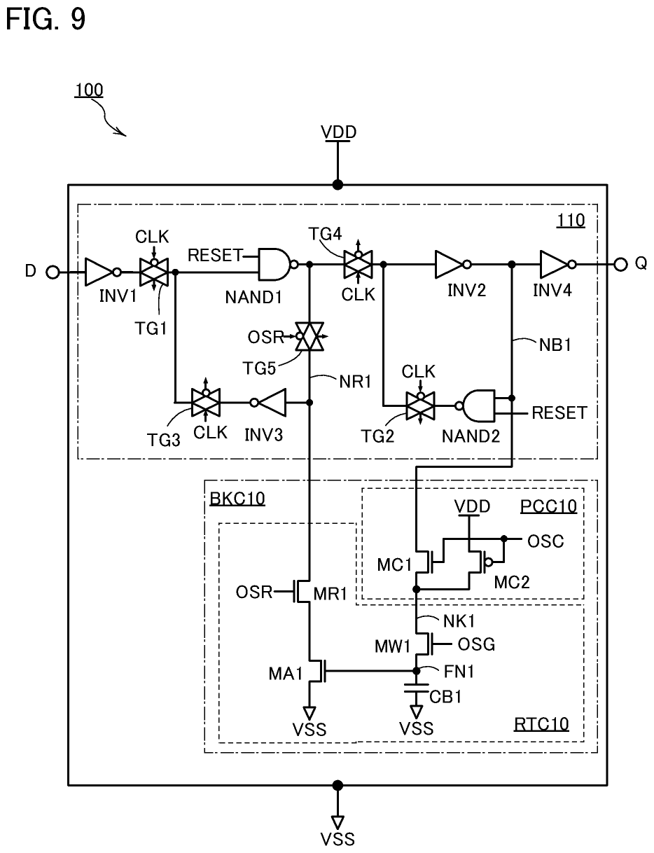

A specific structure example of the storage circuit 31 illustrated in FIG. 4B is described. FIG. 9 is a circuit diagram illustrating a storage circuit structure example. A storage circuit 100 illustrated in FIG. 9 functions as a flip-flop circuit. In FIG. 9, a signal input to the storage circuit 100 is denoted by a signal D, and a signal output from the storage circuit 100 is denoted by a signal Q.

A standard flip-flop circuit (FF) can be used as the circuit MemC1, and for example, a master slave FF can be used. Such a structure example is illustrated in FIG. 9. An FF 110 includes transmission gates (TG1, TG2, TG3, TG4, and TG5), inverter circuits (INV1, INV2, INV3, and INV4), and NAND circuits (NAND1 and NAND2). A signal RESET and a signal OSR are control signals output from the PMU 60. The signal OSR and an inverted signal thereof are input to TG5. A clock signal CLK and an inverted signal thereof are input to TG1 to TG4. One clocked inverter circuit may be provided instead of TG1 and INV1. One clocked NAND circuit may be provided instead of TG2 and NAND2. A clocked inverter circuit may be provided instead of TG3 and INV3. TG5 functions as a switch that controls conduction between an output node of NAND1 and a node NR1. A node NB1 is electrically connected to an input node of a circuit BKC10, and the node NR1 is electrically connected to an output node of the circuit BKC10.

The circuit BKC10 illustrated in FIG. 9 functions as a backup circuit of the FF 110. The circuit BKC10 includes a circuit RTC10 and a circuit PCC10. Signals (OSG, OSC, and OSR) input to the circuit BKC10 are control signals output from the PMU 60. A power supply potential VSS is a low power supply potential and, for example, may be a ground potential (GND) or 0 V. As in the circuit BKC10, the power supply potential VSS and the power supply potential VDD are input to the FF 110. In the storage circuit 100, supply of VDD is controlled by the PMU 60.

The circuit RTC10 includes the transistor MW1, a transistor MA1, a transistor MR1, the capacitor CB1, the node FN1, and a node NK1. The circuit RTC10 has a function of retaining data, and here, includes a 3T gain-cell storage circuit. The transistor MW1 is an OS transistor serving as a write transistor. The transistor MR1 is a read transistor, and the transistor MA1 functions as an amplifier transistor and a read transistor. The node FN1 retains data. The node NK1 is a data input node. The node NR1 is a data output node of the circuit RTC10.

FIG. 9 illustrates a structure example in which the circuit BKC10 reads out data of a slave latch circuit in the FF 110 in a saving operation and restores the retained data to a master latch circuit in a restoration operation. Data to be saved may be data of the master latch circuit. In addition, data may be restored to the slave latch circuit. In that case, TG5 is provided in the slave latch circuit.

The transistor MR1 and the transistor MA1 in the circuit RTC10 may be either n-channel transistors or p-channel transistors, and the levels of the potential of the signal OSR and a power supply potential supplied to the transistor MA1 may be changed depending on the conductivity types of the transistor MR1 and the transistor MA1. In addition, a logic circuit of the FF 110 may be set as appropriate. For example, in the case where the transistor MR1 and the transistor MA1 are p-channel transistors, NAND1 and INV3 are replaced with each other in the master latch circuit and INV2 and NAND2 are replaced with each other in the slave latch circuit. Furthermore, VDD is input to the transistor MA1 instead of VSS.

Data is written with voltage in the circuit BKC10; thus, the write power of the circuit BKC10 can be lower than that of an MRAM in which writing is performed with current. Furthermore, unlike in a flash memory, the number of data rewriting times is not limited because data is retained by the load capacitance of the node FN1.

In the circuit RTC10, energy required for data writing corresponds to energy required for charging and discharging of charge in the capacitor CB1. By contrast, in a storage circuit including a two-terminal storage element such as an MRAM, energy required for data writing corresponds to energy consumed when a current flows to the storage element. Thus, as compared with an MRAM or the like in which a current continuously flows during a data writing period, the circuit BKC10 can reduce energy consumed by data saving. Accordingly, as compared with the case of providing an MRAM, BET (break even time) can be shortened in the case of providing the circuit BKC10 as a backup circuit. Consequently, opportunities of performing power gating by which energy consumption can be reduced are increased, so that the power consumption of the semiconductor device can be reduced.

The circuit PCC10 includes a transistor MC1 and a transistor MC2. The circuit PCC10 has a function of precharging the node FN1. The circuit PCC10 is not necessarily provided. As described later, the data saving time of the circuit BKC10 can be shortened by provision of the circuit PCC10.

### <Operation Example of Storage Circuit>

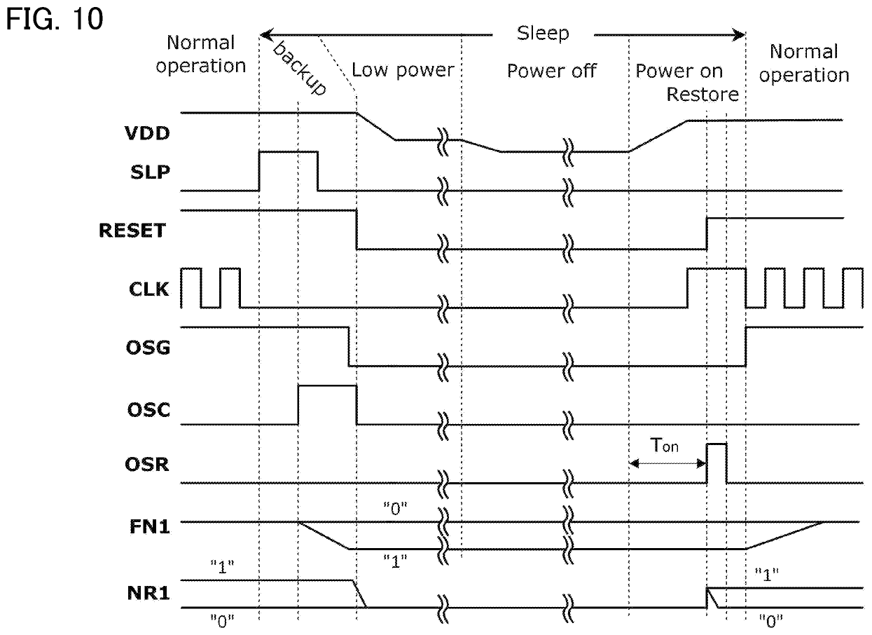

FIG. 10 is a timing chart showing an operation example of the storage circuit 100, and shows changes in waveforms of control signals (the signal SLP, the signal RESET, the clock signal CLK, the signal OSG, the signal OSC, and the signal OSR) and changes in the potentials of the power supply potential VDD, the node FN1, and the node NR1.

### [Normal Operation]

A period of normal operation is described. The power supply potential VDD and the signal CLK are supplied to the storage circuit 100. The FF 110 functions as a sequential circuit. The signal RESET is kept at a high level; thus, NAND1 and NAND2 function as inverter circuits. In the circuit BKC1, the transistor MC1 is in an off state and the transistor MC2 and the transistor MW1 are in an on state, so that the potential of the node FN1 is precharged to a high level.

### [Data Saving]

Next, a period of backup is described. First, supply of the clock signal CLK is stopped. Thus, data rewriting of the node NB1 is stopped. In the example of FIG. 10, the potential level of the node NB1 is at a low level (“0”) when the potential of the node NR1 is at a high level (“1”), and the potential level of the node NB1 is at a high level (“1”) when the potential of the node NR1 is at a low level (“0”). While the signal OSC is at a high level, data of the node NB1 is saved to the node FN1. Specifically, since the transistor MC1 and the transistor MW1 are in an on state, the node FN1 is electrically connected to the node NB1. When the signal OSG is set at a low level to turn off the transistor MW1, the node FN1 is brought into an electrically floating state and the circuit BKC10 retains data. The potential of the node FN1 is at a high level when the node NR1 is at a low level (“0”), and the potential of the node FN1 is at a low level when the node NR1 is at a high level (“1”).

Data saving is terminated by setting the signal OSG at a low level; thus, a voltage scaling operation of the PU 20 can be performed immediately after the signal OSG is set at a low level. In addition, since the node FN1 is precharged to a high level by the transistor MC2 in the normal operation, charge transfer of the node FN1 is not needed in a data saving operation in which the node FN1 is set at a high level. Thus, the circuit BKC10 can complete a saving operation in a short time.

In the data saving operation, the clock signal CLK is inactive. Although the potential of the clock signal CLK is at a low level in the example of FIG. 10, the potential of the clock signal CLK may be at a high level.

### [Voltage Scaling in Low-Power Mode]

Next, a period of low power is described. The PMU 60 performs a voltage scaling operation along with the signal OSC falling. Thus, the storage circuit 100 transitions to the low-power mode.

### [Power Gating in Power-Off Mode]

Next, a period of power off is described. After a certain period of time from transition to the low-power mode, the PMU 60 performs a power gating operation and the storage circuit 100 is transferred to the power-off mode.

### [Power-on Mode]

Next, a period of power on is described. The PMU 60 returns the storage circuit 100 to the power-on mode in response to an interrupt request. In the example of FIG. 10, when the potential of a power supply line for supplying VDD is stabilized, the clock signal CLK is set at a high level.

### [Data Restoration]

While the signal OSR is at a high level, a data restoration operation is performed. When the signal RESET is set at a high level, the potential of the node NR1 is precharged to a high level (“1”). When the signal OSR is set at a high level, TG5 has high impedance and the transistor MR1 is turned on. The conduction state of the transistor MA1 is determined by the potential of the node FN1. When the node FN1 is at a high level, the transistor MA1 is in a conduction state; thus, the potential of the node NR1 is decreased to a low level (“0”). When the node FN1 is at a low level, the potential of the node NR1 is kept at a high level. In other words, the FF 110 returns to the state before transition to the resting state.

As described above, rising of the signal RESET and the signal OSR enables high-level data to be restored to the node NR1. Thus, the restoration operation period of the storage circuit 100 can be shortened.

FIG. 10 shows an example in which the mode returns from the power-off mode to the power-on mode. In the case where the mode returns from the low-power mode to the power-on mode, a period Tₒₙ to stabilization of the potential of the power supply line for supplying VDD is shortened. In that case, rising of the signal OSR is preferably made faster than that when the mode returns from the power-off mode. Note that in FIG. 10, a period from the start of the period of backup to the start of the period of the next normal operation is denoted by a period of sleep (Sleep).

### [Normal Operation]

Next, a period of normal operation is described. By restarting the supply of the clock signal CLK, the storage circuit 100 returns to a state in which a normal operation can be performed. When the signal OSG is set at a high level, the node FN1 is precharged to a high level by the circuit PCC10.

### <<Cache>>

An example in which the cache 40 is formed using an SRAM is described below.

### <Memory Cell Structure Example>

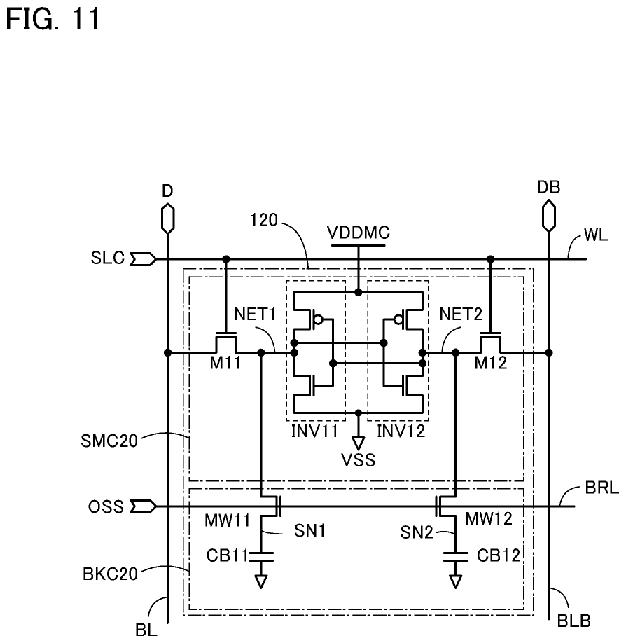

FIG. 11 illustrates a cache memory cell structure example. A memory cell 120 illustrated in FIG. 11 includes a circuit SMC20 and a circuit BKC20. The circuit SMC20 has a circuit structure similar to that of a standard SRAM memory cell. The circuit SMC20 illustrated in FIG. 11 includes an inverter circuit INV11, an inverter circuit INV12, a transistor M11, and a transistor M12.

The circuit BKC20 functions as a backup circuit of the circuit SMC20. The circuit BKC20 includes a transistor MW11, a transistor MW12, a capacitor CB11, and a capacitor CB12. The transistors MW11 and MW12 are OS transistors. The circuit BKC20 includes two 1T1C retention circuits, and a node SN1 and a node SN2 each retain data. A retention circuit formed using the transistor MW11 and the capacitor CB11 has a function of backing up data of a node NET1. A retention circuit formed using the transistor MW12 and the capacitor CB12 has a function of backing up data of a node NET2.

Power supply potentials VDDMC and VSS are supplied to the memory cell 120. The memory cell 120 is electrically connected to wirings (WL, BL, BLB, and BRL). A signal SLC is input to the wiring WL. A data signal D and a data signal DB are input to the wiring BL and the wiring BLB, respectively, at the time of data writing. Data is read out by detection of the potentials of the wiring BL and the wiring BLB. A signal OSS is input to the wiring BRL. The signal OSS is input from the PMU 60.

### <Operation Example of Memory Cell>

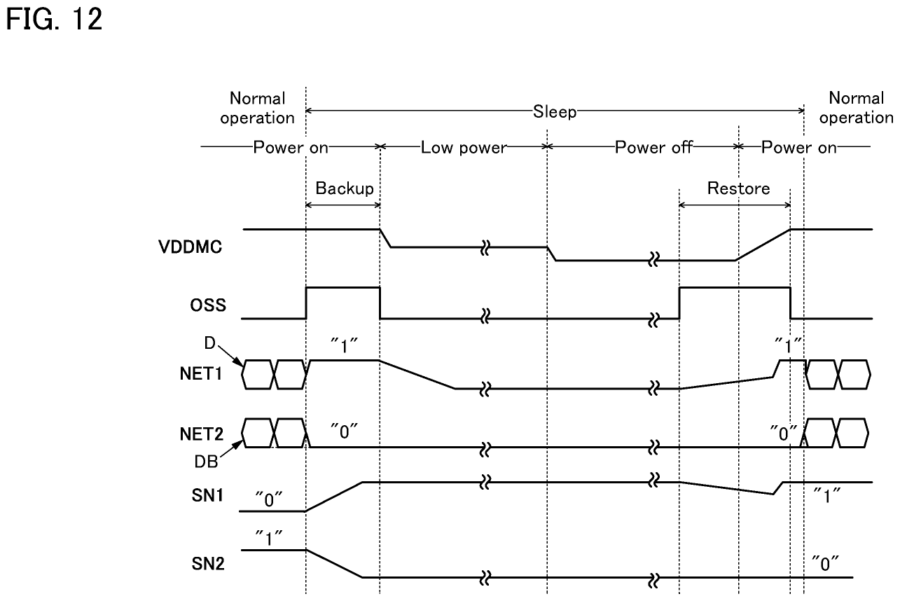

An operation example of the memory cell 120 is described. FIG. 12 is an example of a timing chart for the memory cell 120.

### [Normal Operation]

An access request is input to the circuit MemC2, and data is written and read out. In the circuit BKC2, the signal OSS is at a low level; thus, the node SN1 and the node SN2 are electrically floating and data is retained. In the example of FIG. 12, the potential of the node SN1 is at a low level (“0”) and the potential of the node SN2, which is the other node, is at a high level (“1”).

### [Data Saving]

When the signal OSS is at a high level, the transistors MW11 and MW12 are turned on and the nodes SN1 and SN2 have the same potential levels as the nodes NET1 and NET2. In the example of FIG. 12, the potentials of the nodes SN1 and SN2 are set at a high level and a low level, respectively. The signal OSS is set at a low level and the circuit BKC20 retains data, so that a data saving operation is terminated.

### [Voltage Scaling in Low-Power Mode]

The PMU 60 performs a voltage scaling operation along with the signal OSS falling. Thus, the cache 40 transitions to the low-power mode.

### [Power Gating in Power-Off Mode]

After a certain period of time from transition to the low-power mode, the PMU 60 performs a power gating operation and the cache 40 transitions to the power-off mode.

### [Data Restoration in Power-on Mode]

The PMU 60 returns the cache 40 to a normal state in response to an interrupt request. The signal OSS is set at a high level to restore data retained in the circuit BKC20 to the circuit SMC20. While the signal OSS is at a high level, the PMU 60 performs a voltage scaling operation and a power gating operation and returns the storage circuit 100 to the power-on mode. In the example of FIG. 10, when the potential of the power supply line for supplying VDD is stabilized, the clock signal CLK is set at a high level. When the potential of a power supply line for supplying VDDMC is stabilized, the signal OSS is set at a low level to terminate a data restoration operation. The nodes SN1 and SN2 return to the states immediately before the resting states. Note that in FIG. 12, a period from the start of the period of backup to the start of the period of the next normal operation is denoted by a period of sleep (Sleep).

### [Normal Operation]

When the supply of VDDMC is restarted, the circuit SMC20 returns to a normal mode in which a normal operation can be performed.

As described above, with the use of an OS transistor, a backup circuit capable of retaining data for a long time even when power supply is stopped can be formed. This backup circuit enables power gating of a processor core and a cache. In addition, when power management in which voltage scaling is combined with power gating is performed in a resting state, energy and time overheads due to the return from the resting state to a normal state can be reduced. Thus, power can be reduced efficiently without a decrease in the processing performance of a processing unit.

### <Example of Memory>

A memory using the OS transistor of one embodiment of the present invention is shown below.

A power storage device included in one embodiment of the present invention preferably includes a memory. As the memory, a memory device using an OS transistor can be used. For example, a NOSRAM (registered trademark) or a DOSRAM (registered trademark) which are described below can be used.

A NOSRAM is a gain cell DRAM in which a write transistor of a memory cell is an OS transistor. A NOSRAM is an abbreviation for Nonvolatile Oxide Semiconductor RAM. A structure example of a NOSRAM is described below.

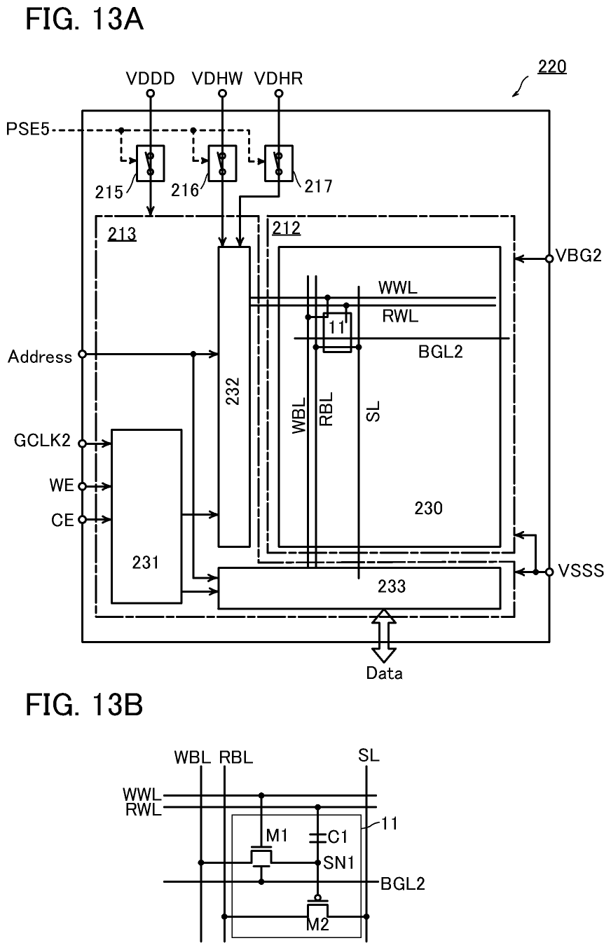

FIG. 13A is a block diagram illustrating a structure example of a NOSRAM. In a NOSRAM 220, power domains 212 and 213 and power switches 215 to 217 are provided. A memory cell array 230 is provided in the power domain 212, and a peripheral circuit of the NOSRAM 220 is provided in the power domain 213. The peripheral circuit includes a control circuit 231, a row circuit 232, and a column circuit 233.

A voltage VDDD, a voltage VSSS, a voltage VDHW, a voltage VDHR, a voltage VBG2, a clock signal GCLK2, an address signal Address, a signal CE, WE, and PSES are input to the NOSRAM 220 from the outside. The signal CE and the signal WE are a chip enable signal and a write enable signal. The signal PSES controls the on/off of the power switches 215 to 217. The power switches 215 to 217 control the input of the voltage VDDD, the voltage VDHW, and the voltage VDHR, respectively, to the power domain 213.

Note that the voltages, signals, and the like input to the NOSRAM 220 are appropriately selected in accordance with the circuit structure and operation method of the NOSRAM 220. For example, the NOSRAM 220 may be provided with a power domain which is not power gated, and a power gating control circuit that generates the signal PSES may be provided.

The memory cell array 230 includes a memory cell 11, a write word line WWL, a readout word line RWL, a write bit line WBL, a readout bit line RBL, and a source line SL.

As illustrated in FIG. 13B, the memory cell 11 is a 2T1C (two transistors and one capacitor) gain cell, which includes a node SN1, transistors M1 and M2, and a capacitor C1. The transistor M1 is a write transistor, which is an OS transistor having a back gate. The back gate of the transistor M1 is electrically connected to a wiring BGL2 for supplying the voltage VBG2. The transistor M2 is a readout transistor, which is a p-channel Si transistor. The capacitor C1 is a storage capacitor for retaining the voltage of the node SN1.

The voltage VDDD and the voltage VSSS are voltages representing data “1” and “0”. Note that high-level voltages of the write word line WWL and the readout word line RWL are the voltage VDHW and the voltage VHDR.

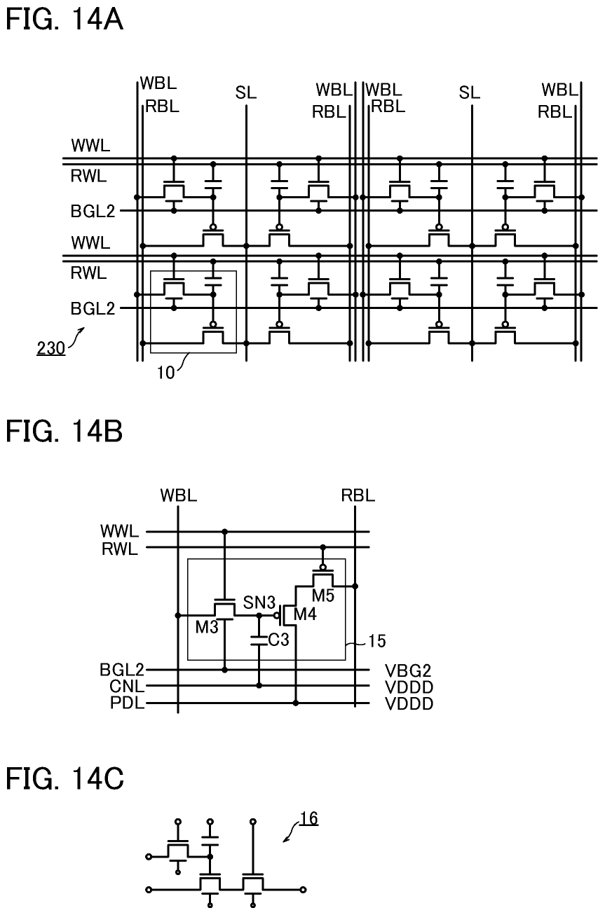

FIG. 14A shows a structure example of the memory cell array 230. In the memory cell array 230 shown in FIG. 14, one source line is supplied to the adjacent two rows.

The memory cell 11 does not have a limitation on the number of rewriting times in principle, can perform data rewriting with low energy, and does not consume power in retaining data. Since the transistor M1 is an OS transistor with an extremely low off-state current, the memory cell 11 can retain data for a long time.

The circuit structure of the memory cell 11 is not limited to the circuit structure shown in FIG. 13B. For example, the readout transistor M2 may be an OS transistor having a back gate or an n-channel Si transistor. Alternatively, the memory cell 11 may be a 3T gain cell. For example, FIG. 14B and FIG. 14C show examples of a 3T gain cell. A memory cell 15 shown in FIG. 14B includes transistors M3 to M5, a capacitor C3, and a node SN3. The transistors M3 to M5 are a write transistor, a readout transistor, and a selection transistor. The transistor M3 is an OS transistor having a back gate, and the transistors M4 and M5 are p-channel Si transistors. The transistors M4 and M5 may each be an n-channel Si transistor or an OS transistor having a back gate. In a memory cell 16 shown in FIG. 14C, three transistors are OS transistors each having a back gate.

The node SN3 is a retention node. The capacitor C3 is a storage capacitor for retaining the voltage of the node SN3. The capacitor C3 may be omitted intentionally, and the storage capacitor may be formed using gate capacitance of the transistor M4, or the like. A wiring PDL is an alternative to the source line SL, and a fixed voltage, for example, the voltage VDDD is input.

The control circuit 231 has a function of controlling the entire operation of the NOSRAM 220. For example, the control circuit 231 performs a logical operation of the signal CE and the signal WE to judge whether access from the outside is write access or readout access.

The row circuit 232 has a function of selecting the write word line WWL and the readout word line RWL in the row selected and specified by the address signal. The column circuit 233 has a function of writing data to the write bit line WBL in the column specified by the address signal and a function of reading out data from the readout bit line RBL in the column.

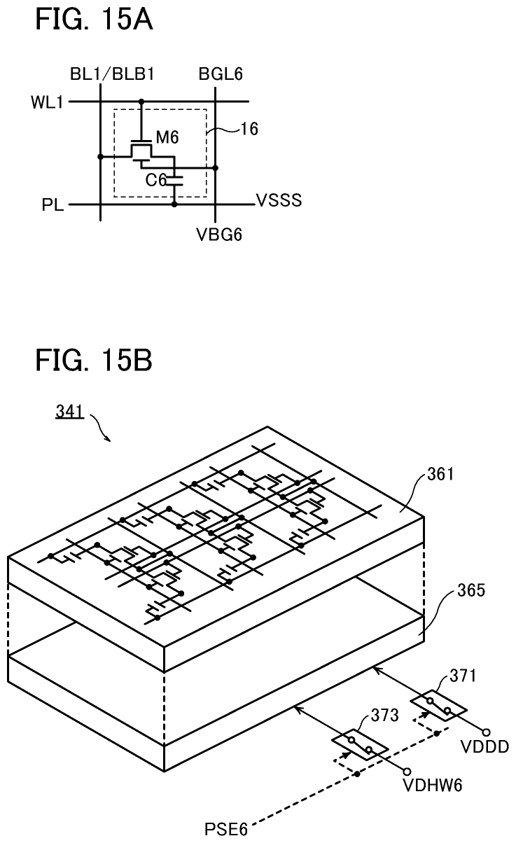

A DOSRAM refers to a RAM including a 1T1C memory cell and is an abbreviation for Dynamic Oxide Semiconductor RAM. A DOSRAM is described below with reference to FIG. 15.

As illustrated in FIG. 15A, the memory cell 16 of a DOSRAM 341 is electrically connected to a bit line BL1 (or BLB1), a word line WL1, and wirings BGL6 and PL. The bit line BLB1 is an inverted bit line. For example, voltages VBG6 and VSSS are input to the wirings BGL6 and PL. The memory cell 16 includes a transistor M6 and a capacitor C6. The transistor M6 is an OS transistor having a back gate.

There is no limitation on the number of rewriting operations of the DOSRAM 341 in principle because data is rewritten by charging and discharging of the capacitor C6; and data can be written and read out with low energy. In addition, the memory cell 16 has a simple circuit structure, and thus the capacity can be easily increased. Since the write transistor of the memory cell 16 is an OS transistor, the retention time of the DOSRAM 341 is significantly longer than that of a DRAM. This allows less frequent refresh or makes refresh operations unnecessary; thus, the power needed for refresh operations can be reduced.

As illustrated in FIG. 15B, in the DOSRAM 341, a memory cell array 361 can be stacked over a peripheral circuit 365. This is because the transistor M6 of the memory cell 16 is an OS transistor.

In the memory cell array 361, a plurality of memory cells 16 are arranged in a matrix, and the bit lines BL1 and BLB1, the word line WL1, and the wirings BGL6 and PL are provided according to the arrangement of the memory cells 16. A control circuit, a row circuit, and a column circuit are provided in the peripheral circuit 365. The row circuit selects the word line WL that is to be accessed, for example. The column circuit performs writing and reading out of data to and from a bit line pair formed of BL and BLB, for example.

Power switches 371 and 373 are provided in order to power gate the peripheral circuit 365. The power switches 371 and 373 control the input of voltages VDDD and VDHW6, respectively, to the peripheral circuit 365. Note that the voltage VDHW6 is a high-level voltage for the word line WL1. On/off of the power switches 371 and 373 is controlled with a signal PSE6.

### <Example of Arithmetic Circuit>

Next, a structure example of a semiconductor device which can be used for an arithmetic operation of a neural network is described.

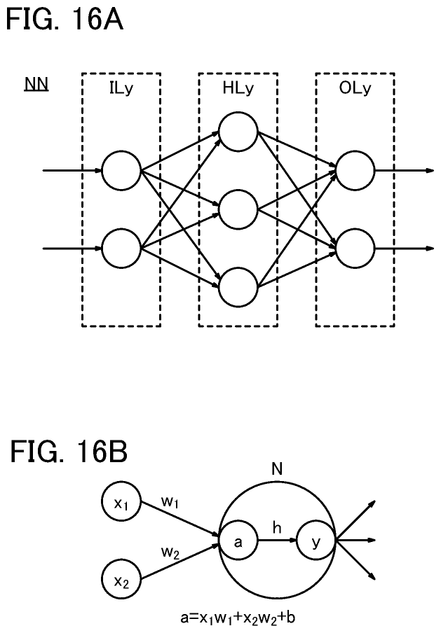

As shown in FIG. 16A, a neural network NN can be formed of an input layer ILy, an output layer OLy, and a middle layer (hidden layer) HLy. The input layer ILy, the output layer OLy, and the middle layer HLy each include one or more neurons (units). Note that the middle layer HLy may be composed of one layer or two or more layers. A neural network including two or more middle layers HLy can also be referred to as a DNN (deep neural network), and learning using a deep neural network can also be referred to as deep learning.

Input data is input to neurons in the input layer ILy, output signals of neurons in the previous layer or the subsequent layer are input to neurons in the middle layer HLy, and output signals of neurons in the previous layer are input to neurons in the output layer OLy. Note that each neuron may be connected to all the neurons in the previous and subsequent layers (full connection), or may be connected to some of the neurons.

FIG. 16B shows an example of a calculation with the neurons. Here, a neuron N and two neurons in the previous layer which output signals to the neuron N are illustrated. An output x₁ of a neuron in the previous layer and an output x₂ of a neuron in the previous layer are input to the neuron N. Then, in the neuron N, a total sum x₁w₁+x₂w₂ of a multiplication result (x₁w₁) of the output x₁ and a weight w₁ and a multiplication result (x₂w₂) of the output x₂ and a weight w₂ is calculated, and then a bias b is added as necessary, so that a value a=x₁w₁+x₂w₂+b is obtained. Then, the value a is converted with an activation function h, and an output signal y=h(a) is output from the neuron N.

In this manner, the calculation with the neurons includes the calculation that sums the products of the outputs and the weights of the neurons in the previous layer, that is, the product-sum operation (x₁w₁+x₂w₂ described above). This product-sum operation may be performed using a program on software or using hardware. In the case where the product-sum operation is performed by hardware, a product-sum operation circuit can be used. Either a digital circuit or an analog circuit can be used as this product-sum operation circuit. In the case where an analog circuit is used as the product-sum operation circuit, the circuit scale of the product-sum operation circuit can be reduced, or higher processing speed and lower power consumption can be achieved by reduced frequency of access to a memory.

The product-sum operation circuit may be formed using a transistor including silicon (such as single crystal silicon) in a channel formation region (hereinafter, also referred to as a Si transistor) or may be formed using a transistor including an oxide semiconductor in a channel formation region (hereinafter, also referred to as an OS transistor). An OS transistor is particularly preferably used as a transistor included in a memory of the product-sum operation circuit because of its extremely low off-state current. Note that the product-sum operation circuit may include both a Si transistor and an OS transistor. A structure example of a semiconductor device having a function of the product-sum operation circuit is described below.

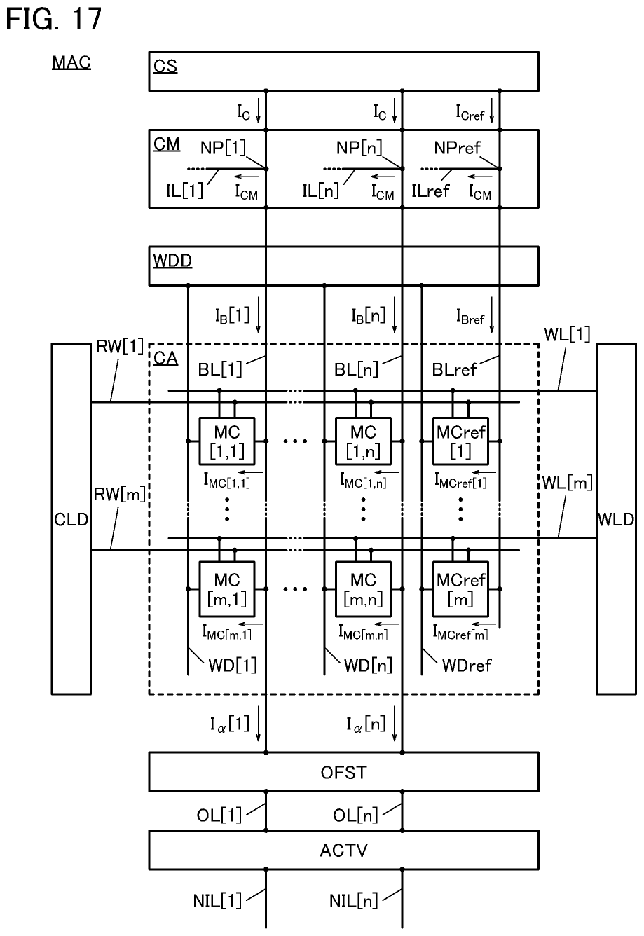

FIG. 17 shows a structure example of a semiconductor device MAC having a function of performing a calculation of a neural network. The semiconductor device MAC has a function of performing a product-sum operation of first data corresponding to the connection strength (weight) between the neurons and second data corresponding to input data. Note that the first data and the second data can each be analog data or multilevel digital data (discrete data). The semiconductor device MAC also has a function of converting data obtained by the product-sum operation with an activation function.

The semiconductor device MAC includes a cell array CA, a current source circuit CS, a current mirror circuit CM, a circuit WDD, a circuit WLD, a circuit CLD, an offset circuit OFST, and an activation function circuit ACTV.

The cell array CA includes a plurality of memory cells MC and a plurality of memory cells MCref FIG. 17 illustrates a structure example in which the cell array CA includes the memory cells MC in m rows and n columns (MC[1, 1] to MC[m, n]) and the m memory cells MCref (MCref[1] to MCref[m]) (m and n are integers greater than or equal to 1). The memory cells MC each have a function of storing the first data. In addition, the memory cells MCref each have a function of storing reference data used for the product-sum operation. Note that the reference data can be analog data or multilevel digital data.

The memory cell MC[i, j] (i is an integer greater than or equal to 1 and less than or equal to m, and j is an integer greater than or equal to 1 and less than or equal to n) is connected to a wiring WL[i], a wiring RW[i], a wiring WD[j], and a wiring BL[j]. In addition, the memory cell MCref[i] is connected to the wiring WL[i], the wiring RW[i], a wiring WDref, and a wiring BLref. Here, a current flowing between the memory cell MC[i, j] and the wiring BL[j] is denoted by I_{MC[i, j]}, and a current flowing between the memory cell MCref[i] and the wiring BLref is denoted by I_{MCref[i]}.

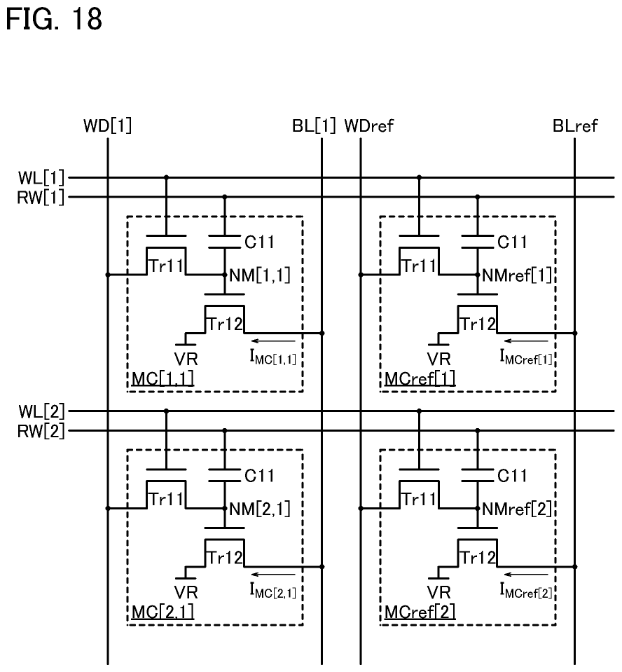

FIG. 18 shows a specific structure example of the memory cells MC and the memory cells MCref Although the memory cells MC[1, 1] and MC[2, 1] and the memory cells MCref[1] and MCref[2] are illustrated in FIG. 18 as typical examples, similar structures can be used for other memory cells MC and memory cells MCref. The memory cells MC and the memory cells MCref each include transistors Tr11 and Tr12 and a capacitor C11. Here, the case where the transistor Tr11 and the transistor Tr12 are n-channel transistors is described.

In the memory cell MC, a gate of the transistor Tr11 is connected to the wiring WL, one of a source and a drain is connected to a gate of the transistor Tr12 and a first electrode of the capacitor C11, and the other of the source and the drain is connected to the wiring WD. One of a source and a drain of the transistor Tr12 is connected to the wiring BL, and the other of the source and the drain of the transistor Tr12 is connected to a wiring VR. A second electrode of the capacitor C11 is connected to the wiring RW. The wiring VR is a wiring having a function of supplying a predetermined potential. Here, the case where a low power supply potential (e.g., a ground potential) is supplied from the wiring VR is described as an example.

A node connected to the one of the source and the drain of the transistor Tr11, the gate of the transistor Tr12, and the first electrode of the capacitor C11 is referred to as a node NM. The nodes NM in the memory cells MC[1, 1] and MC[2, 1] are referred to as nodes NM[1, 1] and NM[2, 1], respectively.

The memory cells MCref have a structure similar to that of the memory cell MC. However, the memory cells MCref are connected to the wiring WDref instead of the wiring WD and connected to the wiring BLref instead of the wiring BL. Nodes in the memory cells MCref[1] and MCref[2] each of which is connected to the one of the source and the drain of the transistor Tr11, the gate of the transistor Tr12, and the first electrode of the capacitor C11 are referred to as nodes NMref[1] and NMref[2], respectively.

The nodes NM and NMref function as retention nodes of the memory cell MC and the memory cell MCref, respectively. The first data is retained in the node NM and the reference data is retained in the node NMref. Currents I_{MC[1, 1]} and I_{MC[2, 1]} from the wiring BL[1] flow to the transistors Tr12 of the memory cells MC[1, 1] and MC[2, 1], respectively. Currents I_{MCref[1]} and I_{MCref[2]} from the wiring BLref flow to the transistors Tr12 of the memory cells MCref[1] and MCref[2], respectively.

Since the transistor Tr11 has a function of retaining the potential of the node NM or the node NMref, the off-state current of the transistor Tr11 is preferably low. Thus, it is preferable to use an OS transistor, which has extremely low off-state current, as the transistor Tr11. This suppresses a change in the potential of the node NM or the node NMref, so that the calculation accuracy can be increased. Furthermore, operations of refreshing the potential of the node NM or the node NMref can be performed less frequently, which leads to a reduction in power consumption.

There is no particular limitation on the transistor Tr12, and for example, a Si transistor, an OS transistor, or the like can be used. In the case where an OS transistor is used as the transistor Tr12, the transistor Tr12 can be manufactured with the same manufacturing apparatus as that for the transistor Tr11, and accordingly manufacturing cost can be reduced. Note that the transistor Tr12 may be an n-channel transistor or a p-channel transistor.

The current source circuit CS is connected to the wirings BL[1] to BL[n] and the wiring BLref. The current source circuit CS has a function of supplying currents to the wirings BL[1] to BL[n] and the wiring BLref. Note that the value of the current supplied to the wirings BL[1] to BL[n] may be different from the value of the current supplied to the wiring BLref. Here, the current supplied from the current source circuit CS to the wirings BL[1] to BL[n] is denoted by I_{C}, and the current supplied from the current source circuit CS to the wiring BLref is denoted by I_{Cref}.

The current mirror circuit CM includes wirings IL[1] to IL[n] and a wiring I_{Lref}. The wirings IL[1] to IL[n] are connected to the wirings BL[1] to BL[n], respectively, and the wiring I_{Lref} is connected to the wiring BLref. Here, portions where the wirings IL[1] to IL[n] are connected to the respective wirings BL[1] to BL[n] are referred to as nodes NP[1] to NP[n]. Furthermore, a connection portion between the wiring I_{Lref} and the wiring BLref is referred to as a node NPref.

The current mirror circuit CM has a function of making a current I_{CM} corresponding to the potential of the node NPref flow to the wiring I_{Lref} and a function of making this current I_{CM} flow also to the wirings IL[1] to IL[n]. In the example illustrated in FIG. 17, the current I_{CM} is discharged from the wiring BLref to the wiring I_{Lref}, and the current I_{CM} is discharged from the wirings BL[1] to BL[n] to the wirings IL[1] to IL[n]. Furthermore, currents flowing from the current mirror circuit CM to the cell array CA through the wirings BL [1] to BL[n] are denoted by I_{B}[1] to I_{B}[n]. Furthermore, a current flowing from the current mirror circuit CM to the cell array CA through the wiring BLref is denoted by I_{Bref}.

The circuit WDD is connected to the wirings WD[1] to WD[n] and the wiring WDref. The circuit WDD has a function of supplying a potential corresponding to the first data stored in the memory cells MC to the wirings WD[1] to WD[n]. The circuit WDD also has a function of supplying a potential corresponding to the reference data stored in the memory cell MCref to the wiring WDref. The circuit WLD is connected to the wirings WL[1] to WL[m]. The circuit WLD has a function of supplying a signal for selecting the memory cell MC or the memory cell MCref to which data is to be written, to any of the wirings WL[1] to WL[m]. The circuit CLD is connected to the wirings RW[1] to RW[m]. The circuit CLD has a function of supplying a potential corresponding to the second data to the wirings RW[1] to RW[m].

The offset circuit OFST is connected to the wirings BL[1] to BL[n] and wirings OL[1] to OL[n]. The offset circuit OFST has a function of detecting the amount of currents flowing from the wirings BL[1] to BL[n] to the offset circuit OFST and/or the amount of change in the currents flowing from the wirings BL[1] to BL[n] to the offset circuit OFST. The offset circuit OFST also has a function of outputting detection results to the wirings OL[1] to OL[n]. Note that the offset circuit OFST may output currents corresponding to the detection results to the wirings OL, or may convert the currents corresponding to the detection results into voltages to output the voltages to the wirings OL. The currents flowing between the cell array CA and the offset circuit OFST are denoted by I_{α}[1] to I_{α}[n].

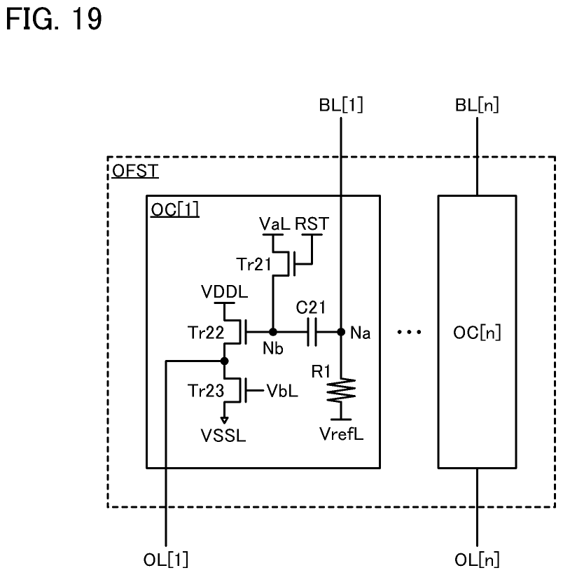

FIG. 19 illustrates a structure example of the offset circuit OFST. The offset circuit OFST illustrated in FIG. 19 includes circuits OC[1] to OC[n]. The circuits OC[1] to OC[n] each include a transistor Tr21, a transistor Tr22, a transistor Tr23, a capacitor C21, and a resistor R1. Connection relationships of the elements are shown in FIG. 19. Note that a node connected to a first electrode of the capacitor C21 and a first terminal of the resistor R1 is referred to as a node Na. In addition, a node connected to a second electrode of the capacitor C21, one of a source and a drain of the transistor Tr21, and a gate of the transistor Tr22 is referred to as a node Nb.

A wiring VrefL has a function of supplying a potential Vref, a wiring VaL has a function of supplying a potential Va, and a wiring VbL has a function of supplying a potential Vb. Furthermore, a wiring VDDL has a function of supplying a potential VDD, and a wiring VSSL has a function of supplying a potential VSS. Here, the case where the potential VDD is a high power supply potential and the potential VSS is a low power supply potential is described. A wiring RST has a function of supplying a potential for controlling the conduction state of the transistor Tr21. The transistor Tr22, the transistor Tr23, the wiring VDDL, the wiring VSSL, and the wiring VbL form a source follower circuit.

Next, an operation example of the circuits OC[1] to OC[n] is described. Note that although an operation example of the circuit OC[1] is described here as a typical example, the circuits OC[2] to OC[n] can operate in a similar manner. First, when a first current flows to the wiring BL[1], the potential of the node Na becomes a potential corresponding to the first current and the resistance value of the resistor R1. At this time, the transistor Tr21 is on, and thus the potential Va is supplied to the node Nb. Then, the transistor Tr21 is turned off.

Next, when a second current flows to the wiring BL[1], the potential of the node Na becomes a potential corresponding to the second current and the resistance value of the resistor R1. At this time, since the transistor Tr21 is off and the node Nb is in a floating state, the potential of the node Nb is changed owing to capacitive coupling, following the change in the potential of the node Na. Here, when the amount of change in the potential of the node Na is ΔV_{Na} and the capacitive coupling coefficient is 1, the potential of the node Nb is Va+ΔV_{Na}. In addition, when the threshold voltage of the transistor Tr22 is Vₜₕ, a potential of Va+ΔV_{Na}−Vₜₕ is output from the wiring OL[1]. Here, when Va=Vₜₕ, the potential ΔV_{Na} can be output from the wiring OL[1].

The potential ΔV_{Na} is determined by the amount of change from the first current to the second current, the resistance value of the resistor R1, and the potential Vref. Here, since the resistance value of the resistor R1 and the potential Vref are known, the amount of change in the current flowing to the wiring BL can be found from the potential ΔV_{Na}.

A signal corresponding to the amount of current and/or the amount of change in the current that are/is detected by the offset circuit OFST as described above is input to the activation function circuit ACTV through the wirings OL[1] to OL[n].

The activation function circuit ACTV is connected to the wirings OL[1] to OL[n] and wirings NIL[1] to NIL[n]. The activation function circuit ACTV has a function of performing a calculation for converting the signal input from the offset circuit OFST in accordance with the predefined activation function. As the activation function, for example, a sigmoid function, a tan h function, a softmax function, a ReLU function, a threshold function, or the like can be used. The signal converted by the activation function circuit ACTV is output as output data to the wirings NIL[1] to NIL[n].

With the above semiconductor device MAC, the product-sum operation of the first data and the second data can be performed. An operation example of the semiconductor device MAC at the time of performing the product-sum operation is described below.

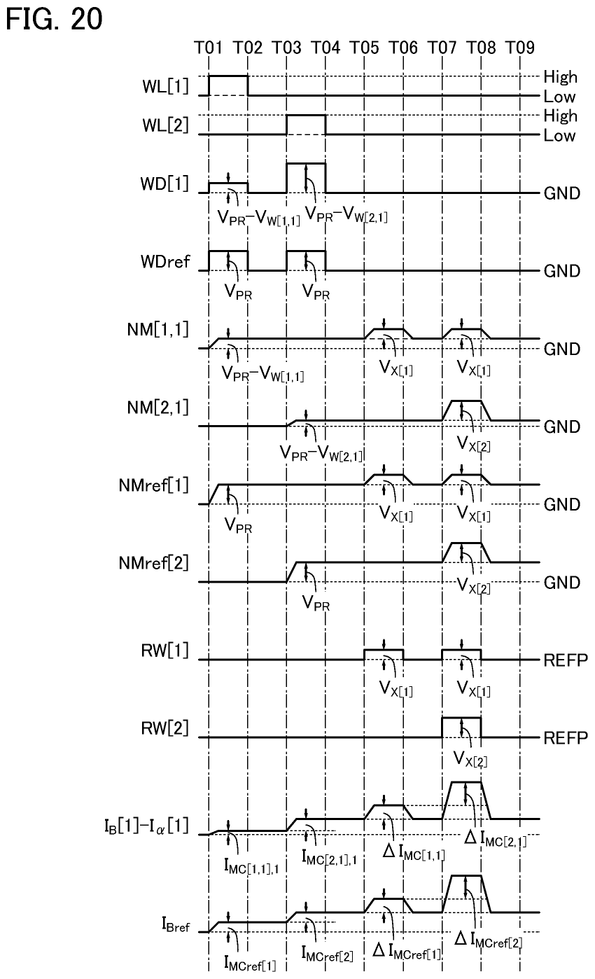

FIG. 20 shows a timing chart of the operation example of the semiconductor device MAC. FIG. 20 shows changes in the potentials of the wiring WL[1], the wiring WL[2], the wiring WD[1], the wiring WDref, the node NM[1, 1], the node NM[2, 1], the node NMref[1], the node NMref[2], the wiring RW[1], and the wiring RW[2] in FIG. 18 and changes in the values of the current I_{B}[1]−I_{α}[1] and the current I_{Bref}. The current I_{B}[1]−I_{α}[1] corresponds to the sum total of the currents flowing from the wiring BL[1] to the memory cells MC[1, 1] and MC[2, 1].

Although an operation is described with a focus on the memory cells MC[1, 1] and MC[2, 1] and the memory cells MCref[1] and MCref[2] illustrated in FIG. 18 as a typical example, the other memory cells MC and the other memory cells MCref can be operated in a similar manner.

First, from Time T01 to Time T02, the potential of the wiring WL[1] becomes a high level (High), the potential of the wiring WD[1] becomes a potential greater than a ground potential (GND) by V_{PR}−V_{W[1, 1]}, and the potential of the wiring WDref becomes a potential greater than the ground potential by V_{PR}. The potentials of the wiring RW[1] and the wiring RW[2] become reference potentials (REFP). Note that the potential V_{W[1, 1]} is a potential corresponding to the first data stored in the memory cell MC[1, 1]. The potential V_{PR} is the potential corresponding to the reference data. Thus, the transistors Tr11 included in the memory cell MC[1, 1] and the memory cell MCref[1] are brought into on states, and the potential of the node NM[2, 1] becomes V_{PR}−V_{W[1, 1]} and the potential of the node NMref[2] becomes V_{PR}.

In this case, a current I_{MC[1, 1], 0} flowing from the wiring BL[1] to the transistor Tr12 in the memory cell MC[1, 1] can be expressed by a formula shown below. Here, k is a constant determined by the channel length, the channel width, the mobility, the capacitance of a gate insulating film, and the like of the transistor Tr12. In addition, Vₜₕ is the threshold voltage of the transistor Tr12.

I_{MC[1, 1], 0}=k(V_{PR}−V_{W[1, 1]}−Vₜₕ)² (E1)

A current I_{MCref[1], 0} flowing from the wiring BLref to the transistor Tr12 in the memory cell MCref[1] can be expressed by a formula shown below.

I_{MCref[1], 0}=k(V_{PR}−Vₜₕ)² (E2)

Next, from Time T02 to Time T03, the potential of the wiring WL[1] becomes a low level (Low). Consequently, the transistors Tr11 included in the memory cell MC[1, 1] and the memory cell MCref[1] are brought into off states, and the potentials of the node NM[1, 1] and the node NMref[1] are retained.

As described above, an OS transistor is preferably used as the transistor Tr11. This can suppress the leakage current of the transistor Tr11, so that the potentials of the node NM[1, 1] and the node NMref[1] can be retained accurately.

Next, Time T03 to Time T04, the potential of the wiring WL[2] becomes the high level, the potential of the wiring WD[1] becomes a potential greater than the ground potential by V_{PR}−V_{W[2, 1]}, and the potential of the wiring WDref becomes a potential greater than the ground potential by V_{PR}. Note that the potential V_{W[2, 1]} is a potential corresponding to the first data stored in the memory cell MC[2, 1]. Thus, the transistors Tr11 included in the memory cell MC[2, 1] and the memory cell MCref[2] are brought into on states, and the potential of the node NM[2, 1] becomes V_{PR}−V_{W[2, 1]} and the potential of the node NMref[2] becomes V_{PR}.

Here, a current I_{MC[2, 1], 0} flowing from the wiring BL[1] to the transistor Tr12 in the memory cell MC[2, 1] can be expressed by a formula shown below.

I_{MC[2,1], 0}=k(V_{PR}−V_{W[2, 1]}−Vₜₕ)² (E3)

Furthermore, a current I_{MCref[2], 0} flowing from the wiring BLref to the transistor Tr12 in the memory cell MCref[2] can be expressed by a formula shown below.

I_{MCref[2], 0}=k(V_{PR}−Vₜₕ)² (E4)

Next, from Time T04 to Time T05, the potential of the wiring WL[2] becomes the low level. Consequently, the transistors Tr11 included in the memory cell MC[2, 1] and the memory cell MCref[2] are brought into off states, and the potentials of the node NM[2, 1] and the node NMref[2] are retained.

Through the above operation, the first data is stored in the memory cells MC[1, 1] and MC[2, 1], and the reference data is stored in the memory cells MCref[1] and MCref[2].

Here, currents flowing through the wiring BL[1] and the wiring BLref from Time T04 to Time T05 are considered. The current is supplied from the current source circuit CS to the wiring BLref. The current flowing through the wiring BLref is discharged to the current mirror circuit CM and the memory cells MCref[1] and MCref[2]. A formula shown below holds where I_{Cref} is the current supplied from the current source circuit CS to the wiring BLref and I_{CM, 0} is the current discharged from the wiring BLref to the current mirror circuit CM.

I_{Cref}−I_{CM, 0}=I_{MCref[1], 0}+I_{MCref[2], 0} (E5)

The current from the current source circuit CS is supplied to the wiring BL[1]. The current flowing through the wiring BL[1] is discharged to the current mirror circuit CM and the memory cells MC[1, 1] and MC[2, 1]. Furthermore, the current flows from the wiring BL[1] to the offset circuit OFST. A formula shown below holds where I_{C, 0} is the current supplied from the current source circuit CS to the wiring BL[1] and I_{α, 0} is the current flowing from the wiring BL[1] to the offset circuit OFST.

I_{C}−I_{CM, 0}=I_{MC[1, 1], 0}+I_{MC[2, 1], 0}+I_{α, 0} (E6)

Next, from Time T05 to Time T06, the potential of the wiring RW[1] becomes a potential greater than the reference potential by V_{X[1]}. At this time, the potential V_{X[1]} is supplied to the capacitor C11 in each of the memory cell MC[1, 1] and the memory cell MCref[1], so that the potential of the gate of the transistor Tr12 is increased because of capacitive coupling. Note that the potential V_{X[1]} is a potential corresponding to the second data supplied to the memory cell MC[1, 1] and the memory cell MCref[1].

The amount of change in the potential of the gate of the transistor Tr12 corresponds to the value obtained by multiplying the amount of change in the potential of the wiring RW by a capacitive coupling coefficient determined by the memory cell structure. The capacitive coupling coefficient is calculated using the capacitance of the capacitor C11, the gate capacitance of the transistor Tr12, the parasitic capacitance, and the like. In the following description, for convenience, the amount of change in the potential of the wiring RW is equal to the amount of change in the potential of the gate of the transistor Tr12, that is, the capacitive coupling coefficient is set to 1. In practice, the potential V_{X} can be determined in consideration of the capacitive coupling coefficient.

When the potential V_{X[1]} is supplied to the capacitors C11 in the memory cell MC[1, 1] and the memory cell MCref[1], the potentials of the node NM[1, 1] and the node NMref[1] each increase by V_{X[1]}.

Here, a current I_{MC[1, 1], 1} flowing from the wiring BL[1] to the transistor Tr12 in the memory cell MC[1, 1] from Time T05 to Time T06 can be expressed by the following formula.

I_{MC[1, 1], 1}=k(V_{PR}−V_{W[1,1]}+V_{X[1]}−Vₜₕ)² (E7)

Thus, when the potential V_{X[1]} is supplied to the wiring RW[1], the current flowing from the wiring BL[1] to the transistor Tr12 in the memory cell MC[1, 1] increases by ΔI_{MC[1, 1]}=I_{MC[1, 1], 1}−I_{MC[1, 1], 0}.

A current I_{MCref[1], 1} flowing from the wiring BLref to the transistor Tr12 in the memory cell MCref[1] from Time T05 to Time T06 can be expressed by the following formula.

I_{MCref[1], 1}=k(V_{PR}+V_{X[1]}−Vₜₕ)² (E8)

Thus, when the potential V_{X[1]} is supplied to the wiring RW[1], the current flowing from the wiring BLref to the transistor Tr12 in the memory cell MCref[1] increases by ΔI_{MCref[1]}=I_{MCref[1], 1}−I_{MCref[1], 0}.

Furthermore, currents flowing through the wiring BL[1] and the wiring BLref are considered. The current I_{Cref} is supplied from the current source circuit CS to the wiring BLref. The current flowing through the wiring BLref is discharged to the current mirror circuit CM and the memory cells MCref[1] and MCref[2]. A formula shown below holds where I_{CM, 1} is the current discharged from the wiring BLref to the current mirror circuit CM.

I_{Cref}−I_{CM, 1}=I_{MCref[1], 1}+I_{MCref[2], 1} (E9)

The current I_{C} from the current source circuit CS is supplied to the wiring BL[1]. The current flowing through the wiring BL[1] is discharged to the current mirror circuit CM and the memory cells MC[1, 1] and MC[2, 1]. Furthermore, the current flows from the wiring BL[1] to the offset circuit OFST. A formula shown below holds where I_{α, 1} is the current flowing from the wiring BL[1] to the offset circuit OFST.

I_{C}−I_{CM, 1}=I_{MC[1, 1], 1}+I_{MC[2,1], 1}+I_{α, 1} (E10)

In addition, from the formula (E1) to the formula (E10), a difference between the current I_{α, 0} and the current I_{α, 1} (differential current ΔI_{α}) can be expressed by a formula shown below.

ΔI_{α}=I_{α, 1}−I_{α, 0}=2kV_{W[1, 1]}V_{X[1]} (E11)

Thus, the differential current ΔI_{α} is a value corresponding to the product of the potentials V_{W[1, 1]} and V_{X[1]}.

After that, from Time T06 to Time T07, the potential of the wiring RW[1] becomes the reference potential, and the potentials of the node NM[1, 1] and the node NMref[1] become similar to the potentials thereof from Time T04 to Time T05.

Next, from Time T07 to Time T08, the potential of the wiring RW[1] becomes a potential greater than the reference potential by V_{X[1]}, and the potential of the wiring RW[2] becomes a potential greater than the reference potential by V_{X[2]}. Accordingly, the potential V_{X[1]} is supplied to the capacitor C11 in each of the memory cell MC[1, 1] and the memory cell MCref[1], and the potentials of the node NM[1, 1] and the node NMref[1] each increase by V_{X[1]} because of capacitive coupling. Furthermore, the potential V_{X[2]} is supplied to the capacitor C11 in each of the memory cell MC[2, 1] and the memory cell MCref[2], and the potentials of the node NM[2, 1] and the node NMref[2] each increase by V_{X[2]} because of capacitive coupling.

Here, a current I_{MC[2, 1], 1} flowing from the wiring BL[1] to the transistor Tr12 in the memory cell MC[2, 1] from Time T07 to Time T08 can be expressed by the following formula.

I_{MCref[2, 1], 1}=k(V_{PR}+V_{W[2, 1]}+V_{X[2]}−Vₜₕ)² (E12)

Thus, when the potential V_{X[2]} is supplied to the wiring RW[2], the current flowing from the wiring BL[1] to the transistor Tr12 in the memory cell MC[2, 1] increases by ΔI_{MC[2, 1]}=I_{MC[2, 1], 1}−I_{MC[2, 1], 0}.

A current I_{MCref[2], 1} flowing from the wiring BLref to the transistor Tr12 in the memory cell MCref[2] from Time T07 to Time T08 can be expressed by the following formula.

I_{MCref[2], 1}=k(V_{PR}−V_{X[2]}−Vₜₕ)² (E13)

Thus, when the potential V_{X[2]} is supplied to the wiring RW[2], the current flowing from the wiring BLref to the transistor Tr12 in the memory cell MCref[2] increases by ΔI_{MCref[2]}=I_{MCref[2], 1}−I_{MCref[2], 0}.

Furthermore, currents flowing through the wiring BL[1] and the wiring BLref are considered. The current I_{Cref} is supplied from the current source circuit CS to the wiring BLref. The current flowing through the wiring BLref is discharged to the current mirror circuit CM and the memory cells MCref[1] and MCref[2]. A formula shown below holds where I_{CM, 2} is the current discharged from the wiring BLref to the current mirror circuit CM.

I_{Cref}−I_{CM, 2}=I_{MCref[1], 1}+I_{MCref[2], 1} (E14)

The current I_{C} from the current source circuit CS is supplied to the wiring BL[1]. The current flowing through the wiring BL[1] is discharged to the current mirror circuit CM and the memory cells MC[1, 1] and MC[2, 1]. Furthermore, the current flows from the wiring BL[1] to the offset circuit OFST. A formula shown below holds where I_{α, 2} is the current flowing from the wiring BL[1] to the offset circuit OFST.

I_{C}−I_{CM, 2}=I_{MC[1, 1], 1}+I_{MC[2, 1], 1}+I_{α, 2} (E15)

In addition, from the formula (E1) to the formula (E8) and the formula (E12) to the formula (E15), a difference between the current I_{α, 0} and the current I_{α, 2} (differential current ΔI_{α}) can be expressed by the following formula.

ΔI_{α}=I_{α,2}−I_{α, 0}=2k(V_{W[1, 1]}V_{X[1]}+V_{W[2, 1]}V_{X[2]}) (E16)

Thus, the differential current ΔI_{α} is a value corresponding to the sum of the product of the potential V_{W[1, 1]} and the potential V_{X[1]} and the product of the potential V_{W[2, 1]} and the potential V_{X[2]}.

After that, from Time T08 to Time T09, the potentials of the wirings RW[1] and RW[2] become the reference potential, and the potentials of the nodes NM[1, 1] and NM[2, 1] and the nodes NMref[1] and NMref[2] become similar to the potentials thereof from Time T04 to Time T05.

As represented by the formula (E11) and the formula (E16), the differential current ΔI_{α} input to the offset circuit OFST can be calculated from the formula including a product term of the potential V_{W} corresponding to the first data (weight) and the potential V_{X} corresponding to the second data (input data). Thus, measurement of the differential current ΔI_{α} with the offset circuit OFST gives the result of the product-sum operation of the first data and the second data.

Note that although the memory cells MC[1, 1] and MC[2, 1] and the memory cells MCref[1] and MCref[2] are particularly focused on in the above description, the number of the memory cells MC and the memory cells MCref can be freely set. In the case where the number m of rows of the memory cells MC and the memory cells MCref is an arbitrary number i, the differential current ΔI_{α} can be expressed by the following formula.

ΔI_{α}=2kΣᵢV_{W[i, 1]}V_{X[i]} (E17)

When the number n of columns of the memory cells MC and the memory cells MCref is increased, the number of product-sum operations executed in parallel can be increased.

The product-sum operation of the first data and the second data can be performed using the semiconductor device MAC as described above. Note that the use of the structure of the memory cells MC and the memory cells MCref in FIG. 18 allows the product-sum operation circuit to be formed of fewer transistors. Accordingly, the circuit scale of the semiconductor device MAC can be reduced.

In the case where the semiconductor device MAC is used for the operation in the neural network, the number m of rows of the memory cells MC can correspond to the number of pieces of input data supplied to one neuron and the number n of columns of the memory cells MC can correspond to the number of neurons. For example, the case where a product-sum operation using the semiconductor device MAC is performed in the middle layer HLy in FIG. 16A is considered. In this case, the number m of rows of the memory cells MC can be set to the number of pieces of input data supplied from the input layer ILy (the number of neurons in the input layer ILy), and the number n of columns of the memory cells MC can be set to the number of neurons in the middle layer HL.

Note that there is no particular limitation on the structure of the neural network for which the semiconductor device MAC is used. For example, the semiconductor device MAC can also be used for a convolutional neural network (CNN), a recurrent neural network (RNN), an autoencoder, a Boltzmann machine (including a restricted Boltzmann machine), and the like.

The product-sum operation of the neural network can be performed using the semiconductor device MAC as described above. Furthermore, the memory cells MC and the memory cells MCref shown in FIG. 18 are used for the cell array CA, which can provide an integrated circuit with improved calculation accuracy, lower power consumption, or a reduced circuit scale.

The structures, methods, and the like described in this embodiment can be used in an appropriate combination with any of the structures, methods, and the like described in the other embodiments and the like.

### Embodiment 2

In this embodiment, an imaging device which can be used in the determination system of one embodiment of the present invention is described.

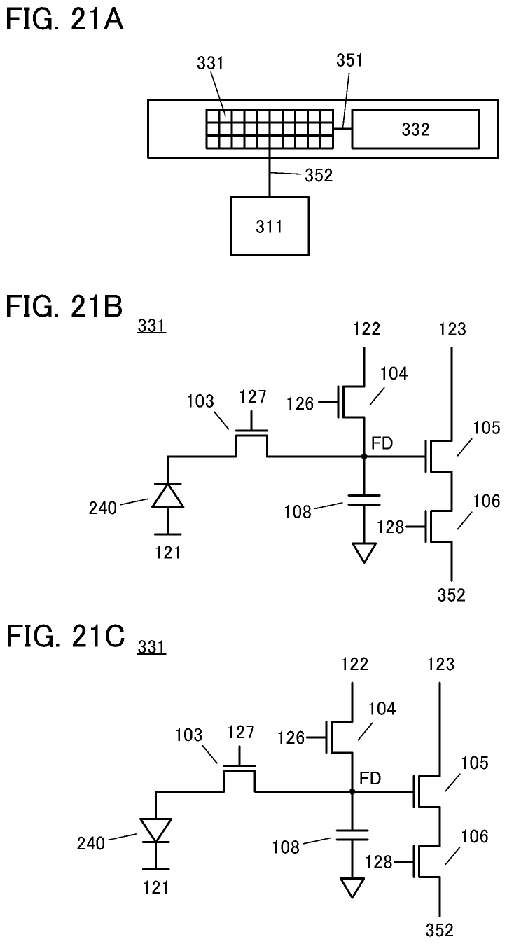

FIG. 21A illustrates a structure example of an imaging device. Pixel circuits 331 are provided in a matrix and are electrically connected to a driver circuit 332 (Driver) through a wiring 351. The driver circuit 332 can control a data acquisition operation, a selection operation, and the like of the pixel circuits 331. As the driver circuit 332, a shift register or the like can be used, for example.

Moreover, the pixel circuits 331 are electrically connected to a reading circuit 311 (RC) through a wiring 352. The reading circuit 311 includes a correlated double sampling circuit (CDS circuit) for reducing noise and an A/D converter for converting analog data into digital data.

The reading circuit 311 is electrically connected to a memory, for example. The memory can retain digital data output from the reading circuit 311.

The A/D converter included in the reading circuit 311 outputs binary data of a predetermined number of bits in parallel. Accordingly, the A/D converter is connected to the memory cells of the predetermined number of bits. For example, when an output of the A/D converter is 8 bits, the A/D converter is connected to eight memory cells.

### <Pixel Circuit>

FIG. 21B is a circuit diagram illustrating an example of the pixel circuit 331. The pixel circuit 331 can include a photoelectric conversion device 240, a transistor 103, a transistor 104, a transistor 105, a transistor 106, and a capacitor 108. Note that a structure not provided with the capacitor 108 may be employed as well.

One electrode (cathode) of the photoelectric conversion device 240 is electrically connected to one of a source and a drain of the transistor 103. The other of the source and the drain of the transistor 103 is electrically connected to one of a source and a drain of the transistor 104. The one of the source and the drain of the transistor 104 is electrically connected to one electrode of the capacitor 108. The one electrode of the capacitor 108 is electrically connected to a gate of the transistor 105. One of a source and a drain of the transistor 105 is electrically connected to one of a source and a drain of the transistor 106.

Here, a wiring that connects the other of the source and the drain of the transistor 103, the one of the source and the drain of the transistor 104, the one electrode of the capacitor 108, and the gate of the transistor 105 is a node FD. The node FD can function as a charge detection portion.

The other electrode (anode) of the photoelectric conversion device 240 is electrically connected to a wiring 121. A gate of the transistor 103 is electrically connected to a wiring 127. The other of the source and the drain of the transistor 104 is electrically connected to a wiring 122. The other of the source and the drain of the transistor 105 is electrically connected to a wiring 123. A gate of the transistor 104 is electrically connected to a wiring 126. A gate of the transistor 106 is electrically connected to a wiring 128. The other electrode of the capacitor 108 is electrically connected to a reference potential line such as a GND wiring, for example. The other of the source and the drain of the transistor 106 is electrically connected to the wiring 352.

The wirings 127, 126, and 128 can have a function of signal lines that control the conduction of the transistors. The wiring 352 can have a function of an output line.

The wirings 121, 122, and 123 can have a function of power supply lines. The structure illustrated in FIG. 21B is a structure in which the cathode side of the photoelectric conversion device 240 is electrically connected to the transistor 103 and the node FD is reset to a high potential in the operation; accordingly, the wiring 122 is set to a high potential (a potential higher than that of the wiring 121).

Although the cathode of the photoelectric conversion device 240 is electrically connected to the node FD in the structure illustrated in FIG. 21B, a structure in which the anode side of the photoelectric conversion device 240 is electrically connected to the one of the source and the drain of the transistor 103 as illustrated in FIG. 21C may be employed as well.

Since the node FD is reset to a low potential in the operation in the structure, the wiring 122 is set to a low potential (a potential lower than that of the wiring 121).

The transistor 103 has a function of controlling the potential of the node FD. The transistor 104 has a function of resetting the potential of the node FD. The transistor 105 functions as a source follower circuit and can output the potential of the node FD as image data to the wiring 352. The transistor 106 has a function of selecting a pixel to which the image data is output.

OS transistors are preferably used as the transistors 103 to 106 included in the pixel circuit 331. The OS transistor has a feature of an extremely low off-state current. In particular, when transistors with a low off-state current are used as the transistors 103 and 104, charge can be retained at the node FD for an extremely long period. Therefore, a global shutter mode in which a charge accumulation operation is performed in all the pixels at the same time can be used without complicating the circuit structure and operation method.

### <Operation Method of Imaging Device>

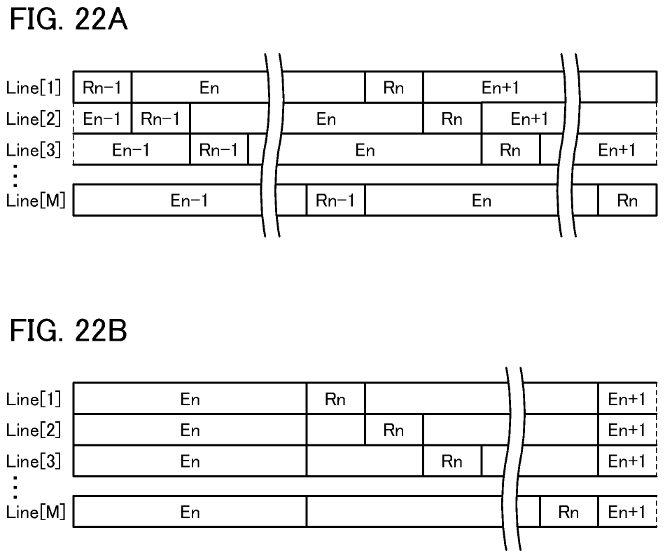

FIG. 22A is a schematic diagram of an operation method with a rolling shutter mode, and FIG. 22B is a schematic diagram of the global shutter mode. Note that En denotes exposure (accumulation operation) in the n-th column (n is a natural number), and Rn denotes a reading operation in the n-th column. In FIG. 22A and FIG. 22B, operations from the first row to the M-th row (M is a natural number) are illustrated.

The rolling shutter mode is an operation method in which exposure and data reading are performed sequentially and a reading period of a row overlaps with an exposure period of another row. The reading operation is performed right after the exposure, so that images can be captured even with a circuit structure having a relatively short data retention period. However, an image of one frame is composed of data that does not have simultaneity of image capturing; therefore, distortion is caused in an image when image capturing of a moving object is performed.

On the other hand, the global shutter mode is an operation method in which exposure is performed on all the pixels at the same time, data is retained in each pixel, and data reading is performed row by row. Thus, an undistorted image can be obtained even when an image of a moving object is captured.

In the case where a transistor with a relatively high off-state current, such as a Si transistor, is used in a pixel circuit, charge easily leaks from a charge detection portion and thus the rolling shutter mode is used in many cases. In order to achieve the global shutter mode using a Si transistor, it is necessary to perform a complicated operation at high speed, for example, to store data in a separate memory circuit. In contrast, when an OS transistor is used in a pixel circuit, the data potential hardly leaks from the charge detection portion; thus, the global shutter mode can be easily achieved. Note that the imaging device of one embodiment of the present invention can also operate in the rolling shutter mode.

Note that the pixel circuit 331 may have a structure in which an OS transistor and a Si transistor are combined freely. Alternatively, all the transistors may be Si transistors.

### <Operation of Pixel Circuit>

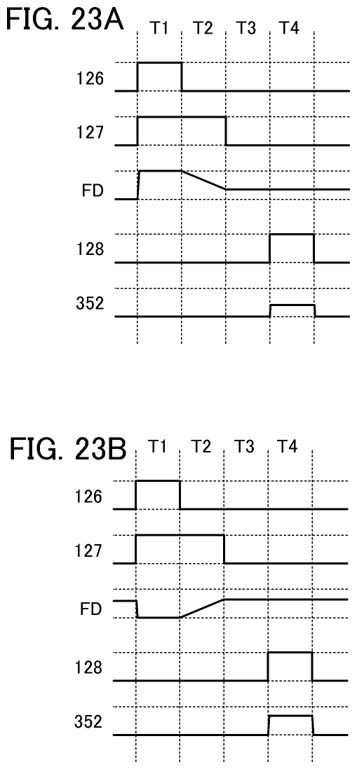

Next, an example of the operation of the pixel circuit illustrated in FIG. 21B is described with reference to a timing chart of FIG. 23A. Note that in the description of the timing chart in this specification, a high potential is denoted by “H” and a low potential is denoted by “L”. The wiring 121 is always supplied with “L”, and the wirings 122 and 123 are always supplied with “H”.

In a period T1, the potential of the wiring 126 is set to “H”, the potential of the wiring 127 is set to “H”, and the potential of the wiring 128 is set to “L”, whereby the transistors 103 and 104 are turned on and the potential “H” of the wiring 122 is supplied to the node FD (reset operation).

In a period T2, the potential of the wiring 126 is set to “L”, the potential of the wiring 127 is set to “H”, and the potential of the wiring 128 is set to “L”, whereby the transistor 104 is turned off and supply of the reset potential is stopped. Furthermore, the potential of the node FD is decreased in accordance with the operation of the photoelectric conversion device 240 (accumulation operation).

In a period T3, the potential of the wiring 126 is set to “L”, the potential of the wiring 127 is set to “L”, and the potential of the wiring 128 is set to “L”, whereby the transistor 103 is turned off and the potential of the node FD is fixed and retained (retention operation). At this time, OS transistors with a low off-state current are used as the transistor 103 and the transistor 104, which are connected to the node FD, whereby unnecessary charge leakage from the node FD can be suppressed and the data retention time can be extended.

In a period T4, the potential of the wiring 126 is set to “L”, the potential of the wiring 127 is set to “L”, and the potential of the wiring 128 is set to “H”, whereby the transistor 106 is turned on and the potential of the node FD is read out to the wiring 352 by a source follower operation of the transistor 105 (reading operation).

The above is an example of the operation of the pixel circuit illustrated in FIG. 21B.

The pixel circuit illustrated in FIG. 21C can operate in accordance with a timing chart of FIG. 23B. The wirings 121 and 123 are always supplied with “H”, and the wiring 122 is always supplied with “L”. The basic operation is similar to that described above with the timing chart of FIG. 23A.

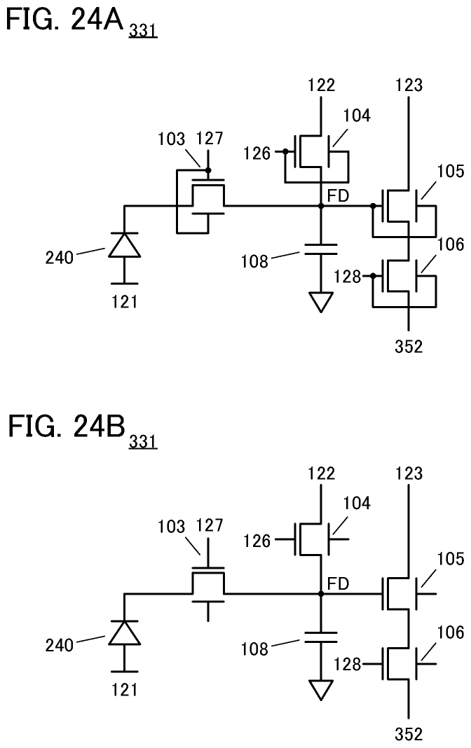

In one embodiment of the present invention, as illustrated in examples of FIG. 24A and FIG. 24B, a structure in which transistors are provided with back gates may be employed. FIG. 24A illustrates a structure in which the back gates are electrically connected to front gates, which has an effect of increasing the on-state current. FIG. 24B illustrates a structure in which the back gates are electrically connected to wirings capable of supplying a constant potential, which enables the threshold voltage of the transistors to be controlled.

A structure in which transistors can operate properly may be employed by combining FIG. 24A and FIG. 24B, for example. Furthermore, the pixel circuit may include a transistor without a back gate.

### <Reading Circuit>

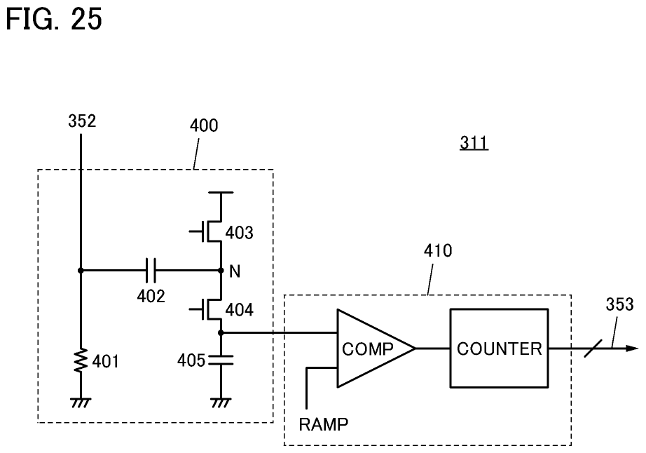

FIG. 25 illustrates an example of the reading circuit 311 connected to the pixel circuit 331, and illustrates a circuit diagram of a CDS circuit 400 and a block diagram of an A/D converter 410 that is electrically connected to the CDS circuit 400. Note that the CDS circuit and the A/D converter illustrated in FIG. 25 are examples, and may each have another structure.

The CDS circuit 400 can include a resistor 401 for voltage conversion, a capacitor 402 for capacitive coupling, a transistor 403 for supplying a potential V₀, a transistor 404 for retaining a potential supplied to the A/D converter 410, and a capacitor 405 for retaining a potential. An input of the CDS circuit 400 is electrically connected to the pixel circuit 331, and an output of the CDS circuit 400 is electrically connected to a comparator circuit (COMP) of the A/D converter 410.

When the potential of the wiring 352 is Vᵣₑₛ (the pixel circuit 331 is in a reset state), the potential of a node N (a connection point of the transistors 403 and 404 and the capacitor 402) is set to V₀. Then, the node N is made into a floating state, and the potential of the wiring 352 becomes V_{data} (the pixel circuit 331 outputs image data); accordingly, the potential of the node N becomes V₀+V_{data}−Vᵣₑₛ. Therefore, in the CDS circuit 400, the potential in the reset state can be subtracted from the potential of the imaging data output from the pixel circuit 331, so that noise components can be reduced.

The A/D converter 410 can include the comparator circuit (COMP) and a counter circuit (COUNTER). In the A/D converter 410, a signal potential input from the CDS circuit 400 to the comparator circuit (COMP) and a swept reference potential (RAMP) are compared. Then, the counter circuit (COUNTER) operates in accordance with the output of the comparator circuit (COMP), and a digital signal is output to a plurality of wirings 353.

### [Stacked Layer Structure 1]

Next, a stacked layer structure of the imaging device is described with reference to a cross-sectional view.

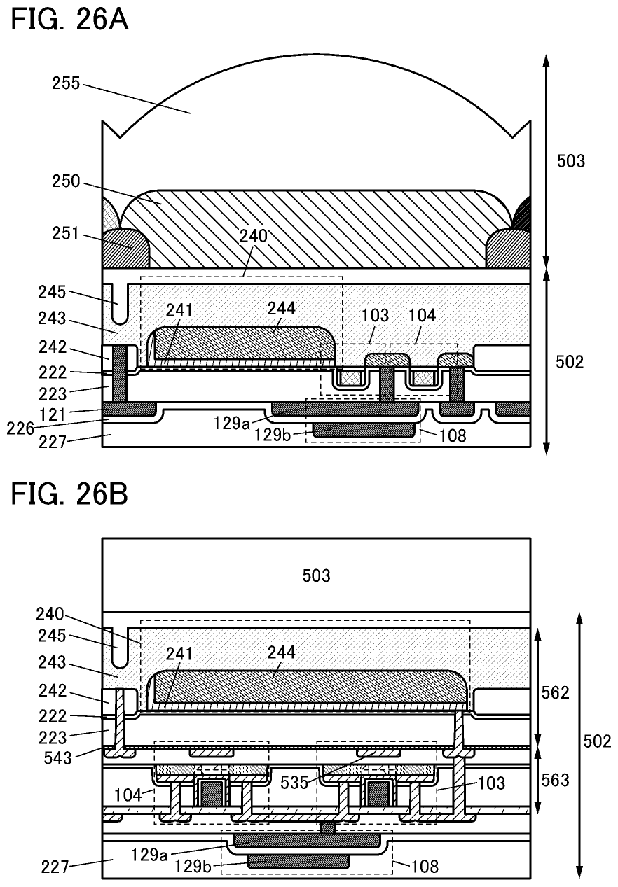

FIG. 26A is an example of a cross-sectional view of a stacked body including a layer 502 and a layer 503.

### <Layer 502>

The layer 502 includes the pixel circuit 331 formed on a silicon substrate. Here, the transistor 103, the transistor 104, the capacitor 108, and the photoelectric conversion device 240 are illustrated as part of the pixel circuit 331.

The photoelectric conversion device 240 is a pn-junction photodiode formed on a silicon substrate and includes a p-type region 243 and an n-type region 244. The photoelectric conversion device 240 is a pinned photodiode, which can suppress a dark current and reduce noise with a p-type region 241 provided on the surface side of the n-type region 244. Note that the p-type region 243 may be used as the p-type region 241. The p-type region 241 preferably has lower resistance than the p-type region 243. Furthermore, the n-type region 244 preferably has lower resistance than the p-type region 243. In addition, in the p-type region 243, the p-type region 241, and the n-type region 244, the p-type regions and the n-type region may be interchanged.

The transistor 103 and the transistor 104 are transistors formed on the silicon substrate. The transistor 103 and the transistor 104 each include a conductive layer functioning as a gate; a source, a drain, and a channel formation region positioned between the source and the drain, which are formed in the silicon substrate; and a gate insulating layer provided between the conductive layer functioning as a gate and the channel formation region. Note that in the example illustrated in FIG. 26A, a source region and a drain region of each of the transistor 103 and the transistor 104 are formed using the n-type region.

In the layer 502, an insulating layer 242 and an insulating layer 245 are provided. The insulating layer 242 functions as an element isolation layer. The insulating layer 245 has a function of suppressing outflow of carriers.

The silicon substrate is provided with a groove that separates pixels, and the insulating layer 245 is provided on the top surface of the silicon substrate and in the groove. The insulating layer 245 can suppress leakage of carriers generated in the photoelectric conversion device 240 to an adjacent pixel. The insulating layer 245 also has a function of suppressing entry of stray light. For example, the grove provided in the insulating layer 245 inhibits entry of stray light from the adjacent pixel in some cases. Therefore, color mixture can be suppressed by the insulating layer 245. Note that an anti-reflection film may be provided between the top surface of the silicon substrate and the insulating layer 245.

The element isolation layer can be formed by a LOCOS (LOCal Oxidation of Silicon) method, an STI (Shallow Trench Isolation) method, or the like. As the insulating layer 245, for example, an inorganic insulating film of silicon oxide film, silicon nitride, or the like or an organic insulating film of polyimide, acrylic, or the like can be used. The insulating layer 245 may have a multilayer structure.

In the example illustrated in FIG. 26A, the n-type region 244 (corresponding to a cathode) of the photoelectric conversion device 240 can also function as one of the source and the drain of the transistor 103.

Furthermore, in the layer 502, insulating layers 222, 223, 226, and 227, the wiring 121, an electrode 129a, and an electrode 129b are provided. The insulating layer 222 has a function of a protective film. The insulating layers 223 and 227 have a function of an interlayer insulating film and a planarization film. The electrode 129a and the electrode 129b each have a function of an electrode of the capacitor 108. The insulating layer 226 is sandwiched between the electrode 129a and the electrode 129b and has a function of a dielectric layer of the capacitor 108. The electrode 129a is electrically connected to the other of the source and the drain of the transistor 103 through a plug provided in the insulating layer 223. The wiring 121 has a function of a power supply line. The p-type region 243 (anode) is electrically connected to the wiring 121.

As the protective film, for example, a silicon nitride film, a silicon oxide film, an aluminum oxide film, or the like can be used. As the interlayer insulating film and the planarization film, for example, an inorganic insulating film such as a silicon oxide film or an organic insulating film of an acrylic resin, a polyimide resin, or the like can be used. As the dielectric layer of the capacitor, a silicon nitride film, a silicon oxide film, an aluminum oxide film, or the like can be used.

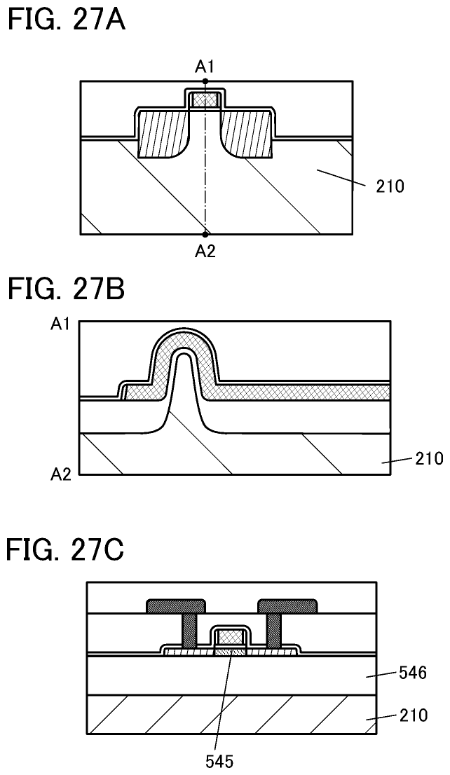

The Si transistors illustrated in FIG. 26A are planar transistors including channel formation regions in the silicon substrate. Note that the Si transistors may have a fin-type structure as illustrated in FIG. 27A. FIG. 27B illustrates a cross section along A1-A2 (cross section in the channel width direction) in FIG. 27A.

Alternatively, a transistor including a semiconductor layer 545 of a silicon thin film as illustrated in FIG. 27C may be used. The semiconductor layer 545 can be single crystal silicon (SOI (Silicon on Insulator)) formed on an insulating layer 546 on the silicon substrate 210, for example.

As a conductor that can be used for a wiring, an electrode, and a plug used for electrical connection between devices, a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements as its component; an alloy containing a combination of the above metal elements; or the like is selected and used as appropriate. The conductor is not limited to a single layer, and may be a plurality of layers including different materials. Trontium or the like may be contained.

### <Layer 503>

The layer 503 is formed over the layer 502. The layer 503 includes a light-blocking layer 251, an optical conversion layer 250, and a microlens array 255.

The light-blocking layer 251 can suppress entry of light into an adjacent pixel. As the light-blocking layer 251, a metal layer of aluminum, tungsten, or the like can be used. The metal layer and a dielectric film functioning as an anti-reflection film may be stacked.

As the optical conversion layer 250, a color filter can be used. When colors of R (red), G (green), B (blue), Y (yellow), C (cyan), M (magenta), and the like are assigned to the color filters of respective pixels, a color image can be obtained.

When a wavelength cut filter is used as the optical conversion layer 250, the imaging device can capture images in various wavelength regions

For example, when a filter that blocks light having a wavelength shorter than or equal to that of visible light is used as the optical conversion layer 250, an infrared imaging device can be obtained. When a filter that blocks light having a wavelength shorter than or equal to that of near infrared light is used as the optical conversion layer 250, a far-infrared imaging device can be obtained. When a filter that blocks light having a wavelength longer than or equal to that of visible light is used as the optical conversion layer 250, an ultraviolet imaging device can be obtained.

Furthermore, when a scintillator is used as the optical conversion layer 250, an imaging device that obtains an image visualizing the intensity of radiation, which is used for an X-ray imaging device or the like, can be obtained. Radiation such as X-rays passes through an object and enters the scintillator, and then is converted into light (fluorescence) such as visible light or ultraviolet light owing to a photoluminescence phenomenon. Then, the photoelectric conversion device 240 detects the light to obtain image data. Furthermore, the imaging device having this structure may be used in a radiation detector or the like.

A scintillator contains a substance that, when irradiated with radiation such as X-rays or gamma-rays, absorbs energy of the radiation to emit visible light or ultraviolet light. For example, a resin or ceramics in which Gd₂O₂S:Tb, Gd₂O₂S:Pr, Gd₂O₂S:Eu, BaFC₁:Eu, NaI, CsI, CaF₂, BaF₂, CeF₃, LiF, LiI, ZnO, or the like is dispersed can be used.

The microlens array 255 is provided over the optical conversion layer 250. Light passing through an individual lens of the microlens array 255 goes through the optical conversion layer 250 directly under the lens, and the photoelectric conversion device 240 is irradiated with the light. With the microlens array 255, collected light can be incident on the photoelectric conversion device 240; thus, photoelectric conversion can be efficiently performed. The microlens array 255 is preferably formed using a resin, glass, or the like with a high visible-light transmitting property.

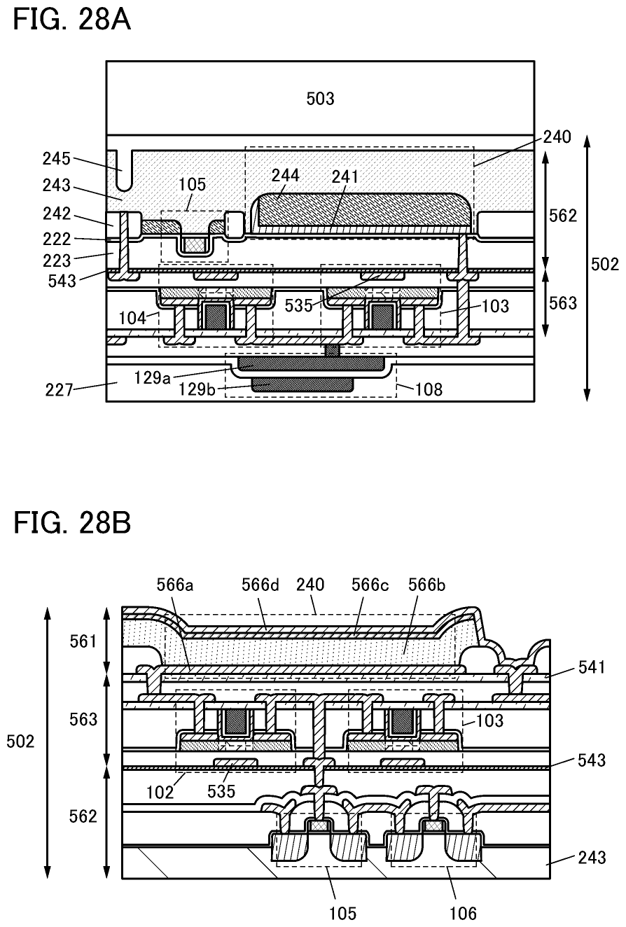

As the transistor 103 and the transistor 104, OS transistors may be used. A stacked layer structure illustrated in FIG. 26B includes the layer 502 and the layer 503, where the layer 502 includes a layer 562 including elements provided on a Si substrate and a layer 563 including OS transistors. The layer 562 illustrated in FIG. 26B includes the photoelectric conversion device 240 provided on the Si substrate. Although a Si transistor is not illustrated in the layer 562 in FIG. 26B, the layer 562 may include the transistor 105 as illustrated in FIG. 28A. Furthermore, although not illustrated, the layer 562 may include the transistor 106. Alternatively, the transistor 105, the transistor 106, and the like may be OS transistors and provided in the layer 563.

The OS transistor has an extremely low off-state current and can retain charge accumulated in the capacitor 108 for a long time.

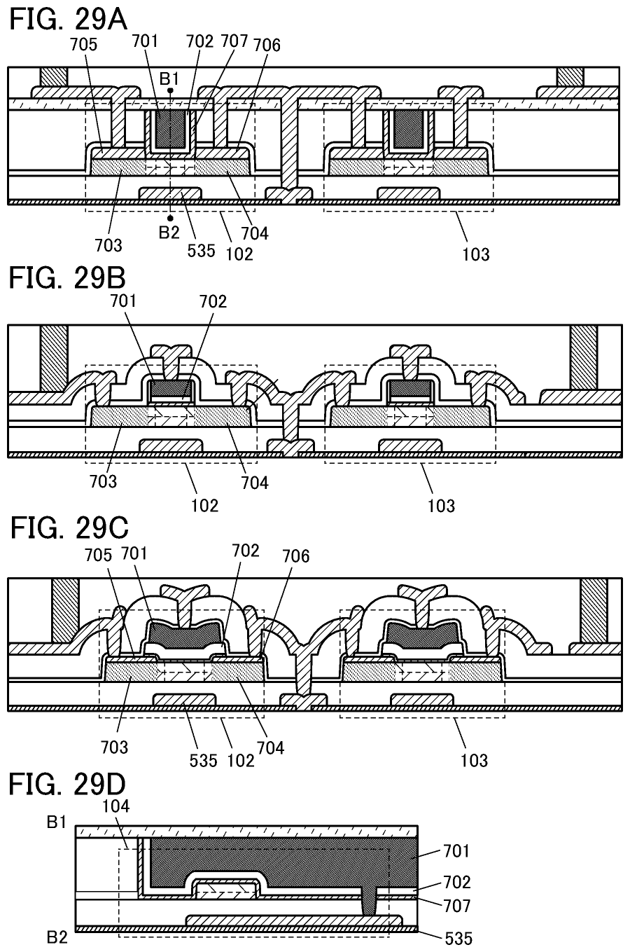

The OS transistor can be provided to be stacked on a Si transistor or the photoelectric conversion device 240 provided on the Si substrate. Accordingly, the circuits can be integrated. Furthermore, the area of the photoelectric conversion device 240 can be increased. OS transistors will be described in detail with reference to FIG. 29.

In a structure illustrated in FIG. 28B, the layer 502 includes a layer 561 in addition to the layer 562 and the layer 563. The layer 561 is a structure example of a case where a pn-junction photodiode using a selenium-based material in a photoelectric conversion layer is used as the photoelectric conversion device 240. A layer 566a is included as one electrode, layers 566b and 566c are included as the photoelectric conversion layer, and a layer 566d is included as the other electrode. The layer 561 can be directly formed on the layer 563. Note that the same connection structure of the transistors applies to the case where an organic photoconductive film is used as the photoelectric conversion device 240 included in the layer 561.

An insulating layer 541 is provided over a transistor 102 and the transistor 103 which are included in the layer 563. The layer 566a includes a region embedded in the insulating layer 541.

The layer 562 of FIG. 28B shows an example where fin transistors are included as the Si transistors. In the example illustrated in FIG. 28B, the transistor 105 and the transistor 106 are provided in the layer 562.

Note that the stacked layer structure of the Si transistors and the OS transistors illustrated in FIG. 28A and FIG. 28B can apply to a structure of Si transistors and OS transistors included in the above-described processing unit (PU). For example, the pixel circuits of the imaging device and the semiconductor device including the above-described processing unit can be formed over the same silicon substrate. Therefore, for example, the pixel circuits and the driver circuit of the imaging device and the semiconductor device included in the determination system of one embodiment of the present invention can be provided on the same chip. When a chip is provided with the structure of the determination system of one embodiment of the present invention, the chip area can be reduced, for example. Furthermore, the pixel circuits and the driver circuit of the imaging device and the semiconductor device included in the processing unit (PU) or the like can be formed through the same process, for example; thus, costs needed to manufacture chips can be reduced. Moreover, when a chip is provided with the structure of the determination system of one embodiment of the present invention, energy needed to transfer images to the memory circuit or the determination circuit included in the semiconductor device can be reduced, for example, whereby arithmetic efficiency can be improved in some cases.

The details of an OS transistor are illustrated in FIG. 29A. The OS transistor illustrated in FIG. 29A has a self-aligned structure in which a source electrode 705 and a drain electrode 706 are formed through provision of an insulating layer over stacked layers of an oxide semiconductor layer and a conductive layer and provision of grooves reaching the oxide semiconductor layer.

The OS transistor can have a structure including a gate electrode 701 and a gate insulating film 702 in addition to a channel formation region, a source region 703, and a drain region 704, which are formed in the oxide semiconductor layer. At least the gate insulating film 702 and the gate electrode 701 are provided in the groove. The groove may further be provided with an oxide semiconductor layer 707.

As illustrated in FIG. 29B, the OS transistor may have a self-aligned structure in which the source region and the drain region are formed in the semiconductor layer with the gate electrode 701 as a mask.

As illustrated in FIG. 29C, the OS transistor may be a non-self-aligned top-gate transistor including a region where the source electrode 705 or the drain electrode 706 overlaps with the gate electrode 701.

Although the transistors 102 and 103 have a structure with a back gate 535, it may have a structure without a back gate. As illustrated in a cross-sectional view of the transistor in the channel width direction in FIG. 29D, the back gate 535 may be electrically connected to a front gate of the transistor, which is provided to face the back gate. Note that FIG. 29D illustrates the transistor of FIG. 21A as an example, and the same applies to a transistor having any of the other structures. Different fixed potentials may be supplied to the back gate 535 and the front gate.

An insulating layer 543 that has a function of inhibiting diffusion of hydrogen is provided between a region where the OS transistors are formed and a region where the Si transistors are formed. Dangling bonds of silicon are terminated with hydrogen in insulating layers provided in the vicinities of the channel formation regions of the transistors 105 and 106. Meanwhile, hydrogen in insulating layers that are provided in the vicinities of the channel formation regions of the transistors 102 and 103 causes generation of carriers in the oxide semiconductor layer.

Hydrogen is confined in the one layer by the insulating layer 543, so that the reliability of the transistors 105 and 106 can be improved. Furthermore, diffusion of hydrogen from the one layer to the other layer is inhibited, so that the reliability of the transistors 102 and 103 can also be improved.

For the insulating layer 543, for example, aluminum oxide, aluminum oxynitride, gallium oxide, gallium oxynitride, yttrium oxide, yttrium oxynitride, hafnium oxide, hafnium oxynitride, or yttria-stabilized zirconia (YSZ) can be used.

The structures, methods, and the like described in this embodiment can be used in an appropriate combination with any of the structures, methods, and the like described in the other embodiments and the like.

### Embodiment 3

In this embodiment, examples of electronic devices in which the semiconductor device of one embodiment of the present invention is used are described.

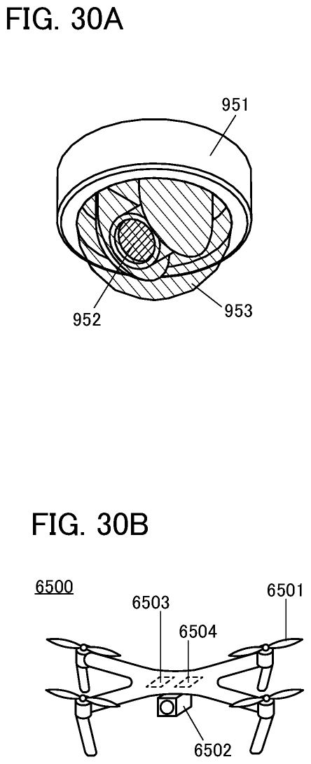

FIG. 30A illustrates a surveillance camera, which includes a support base 951, a camera unit 952, a protection cover 953, and the like. The camera unit 952 is provided with a rotation mechanism and the like and can capture an image of all of the surroundings when provided on a ceiling. The camera unit 952 can be used as the imaging device included in the determination system of one embodiment of the present invention. When the camera unit 952 is electrically connected to the semiconductor device of one embodiment of the present invention, a suspicious person can be identified from the captured image data. Note that a surveillance camera is a name in common use and does not limit the use thereof. For example, a device that has a function of a surveillance camera can also be called a camera or a video camera.

FIG. 30B illustrates an example of a flying object. A flying object 6500 illustrated in FIG. 30B includes propellers 6501, a camera 6502, a battery 6503, and the like and has a function of flying autonomously.

For example, image data taken by the camera 6502 is stored in an electronic component 6504. The electronic component 6504 can analyze the image data to detect whether there is an obstacle in the way of the movement. As the camera 6502, a plurality of kinds of imaging devices may be used. As the imaging device included in the determination system of one embodiment of the present invention, the camera 6502 can be used. When the camera 6502 is electrically connected to the semiconductor device of one embodiment of the present invention, a suspicious person can be identified from the captured image data.

The structures, methods, and the like described in this embodiment can be used in an appropriate combination with any of the structures, methods, and the like described in the other embodiments and the like.

### REFERENCE NUMERALS

ACTV: activation function circuit, BGL2: wiring, BGL6: wiring, BKC1: circuit, BKC2: circuit, BKC10: circuit, BKC20: circuit, BL: wiring, BLref: wiring, BL1: bit line, BLB: wiring, BLB1: bit line, C1: capacitor, C3: capacitor, C6: capacitor, C11: capacitor, C21: capacitor, CA: cell array, CB1: capacitor, CB2: capacitor, CB11: capacitor, CB12: capacitor, CLD: circuit, CM: current mirror circuit, CS: current source circuit, HLy: middle layer, IL: wiring, ILref: wiring, ILy: input layer, INV11: inverter circuit, INV12: inverter circuit, INV2: inverter circuit, INV3: inverter circuit, INV4: inverter circuit, M1: transistor, M11: transistor, M12: transistor, M2: transistor, M3: transistor, M4: transistor, M5: transistor, M6: transistor, MA1: transistor, MAC: semiconductor device, MC: memory cell, MCref: memory cell, MC1: transistor, MC2: transistor, MemC1: circuit, MemC2: circuit, MemC20: circuit, MR1: transistor, MW1: transistor, MW2: transistor, MW11: transistor, MW12: transistor, OFST: offset circuit, OLy: output layer, PCC10: circuit, PDL: wiring, R1: resistor, RBL: bit line, RTC10: circuit, RWL: word line, SMC20: circuit, Tr11: transistor, Tr12: transistor, WBL: bit line, WD: wiring, WDref: wiring, WL: wiring, WL1: word line, WLD: circuit, WWL: word line, 10: power supply circuit, 11: memory cell, 15: memory cell, 16: memory cell, 20: PU, 30: processor core, 31: storage circuit, 32: circuit, 35: power supply line, 40: cache, 41: memory array, 42: peripheral circuit, 43: control circuit, 45: memory cell, 60: PMU, 61: circuit, 65: clock control circuit, 70: PSW, 71: PSW, 80: preliminary determination circuit, 81: memory, 82: circuit, 88: interface, 89: bus line, 91: determination circuit, 92: detection circuit, 100: storage circuit, 102: transistor, 103: transistor, 104: transistor, 105: transistor, 106: transistor, 108: capacitor, 110: FF, 120: memory cell, 121: wiring, 122: wiring, 123: wiring, 126: wiring, 127: wiring, 128: wiring, 129a: electrode, 129b: electrode, 130: processor core, 131: control device, 132: program counter, 133: pipeline register, 134: pipeline register, 135: register file, 136: ALU, 137: data bus, 210: silicon substrate, 212: power domain, 213: power domain, 215: power switch, 217: power switch, 220: NOSRAM, 222: insulating layer, 223: insulating layer, 226: insulating layer, 227: insulating layer, 230: memory cell array, 231: control circuit, 232: row circuit, 233: column circuit, 240: photoelectric conversion device, 241: p-type region, 242: insulating layer, 243: p-type region, 244: n-type region, 245: insulating layer, 250: optical conversion layer, 251: light-blocking layer, 255: microlens array, 311: circuit, 331: pixel circuit, 332: driver circuit, 341: DOSRAM, 351: wiring, 352: wiring, 353: wiring, 361: memory cell array, 365: peripheral circuit, 371: power switch, 373: power switch, 400: CDS circuit, 401: resistor, 402: capacitor, 403: transistor, 404: transistor, 405: capacitor, 410: A/D converter, 502: layer, 503: layer, 535: back gate, 541: insulating layer, 543: insulating layer, 545: semiconductor layer, 546: insulating layer, 561: layer, 562: layer, 563: layer, 566a: layer, 566b: layer, 566c: layer, 566d: layer, 601: imaging device, 602: display device, 603: terminal, 700: semiconductor device, 701: gate electrode, 702: gate insulating film, 703: source region, 704: drain region, 705: source electrode, 706: drain electrode, 707: oxide semiconductor layer, 951: support base, 952: camera unit, 953: protection cover, 6500: flying object, 6501: propeller, 6502: camera, 6503: battery, 6504: electronic component

1. A semiconductor device comprising: a detection circuit; a first determination circuit; a second determination circuit; a power supply circuit; and a power management unit,
wherein the detection circuit is configured to analyze first data and making a first determination of selecting a first value or a second value,
wherein the first determination circuit and the second determination circuit are configured to perform feature extraction of an image,
wherein the power management unit is configured to allow a voltage to be supplied from the power supply circuit to the first determination circuit in the case where the first value is selected by the first determination,
wherein the first determination circuit is configured to analyze the first data and making a second determination, and
wherein the second determination circuit is configured to analyze the first data and making a third determination in the case where an occurrence of an event is detected in the second determination.

2. The semiconductor device according to claim 1,
wherein the first determination circuit is configured to perform contour extraction.

3. The semiconductor device according to claim 1,
wherein the first determination circuit is configured to perform contour extraction, and
wherein the second determination circuit is configured to execute one or more techniques selected from a deep neural network, a convolutional neural network, a recurrent neural network, an autoencoder, a deep Boltzmann machine, and a deep belief network.

4. The semiconductor device according to claim 1,
wherein the event is detection of a human using the contour extraction.

5. The semiconductor device according to claim 1,
wherein the first determination circuit is configured to preform face recognition of a human using the contour extraction.

6. The semiconductor device according to claim 1, further comprising an antenna being configured to transmit a result of the third determination by wireless communication.

7. A determination system comprising: an imaging device; a detection circuit; a processing device; a second determination circuit; and a power supply circuit,
wherein the processing device comprises a first determination circuit, a power management unit, a processor core, and a storage circuit,
wherein the processor core is configured to give an instruction to the first determination circuit,
wherein the storage circuit is configured to retain data generated by the processor core,
wherein the imaging device is configured to obtain first data,
wherein the detection circuit is configured to analyze the first data and making a first determination of selecting a first value or a second value,
wherein the first determination circuit and the second determination circuit are configured to perform feature extraction of an image,
wherein the power management unit is configured to allow a voltage to be supplied from the power supply circuit to the first determination circuit in the case where the first value is selected by the first determination,
wherein the first determination circuit is configured to analyze the first data and making a second determination,
wherein the second determination circuit is configured to analyze the first data and making a third determination in the case where an occurrence of an event is detected in the second determination, and
wherein the imaging device comprises a plurality of pixel circuits arranged in a matrix.

8. The determination system according to claim 7,
wherein the storage circuit comprises a first transistor and a first capacitor,
wherein one of a source and a drain of the first transistor is electrically connected to one electrode of the first capacitor, and
wherein the first transistor comprises an oxide semiconductor in a channel formation region.

9. The determination system according to claim 7,
wherein the storage circuit comprises a first transistor and a first capacitor,
wherein one of a source and a drain of the first transistor is electrically connected to one electrode of the first capacitor,
wherein the first transistor comprises an oxide semiconductor in a channel formation region,
wherein each of the plurality of pixel circuits comprises a photoelectric conversion device, a second transistor, and a second capacitor,
wherein one electrode of the photoelectric conversion device is electrically connected to one of a source and a drain of the second transistor,
wherein the other of the source and the drain of the second transistor is electrically connected to one electrode of the second capacitor, and
wherein the second transistor comprises an oxide semiconductor in a channel formation region.

10. The determination system according to claim 7,
wherein the first determination circuit is configured to perform contour extraction.

11. The determination system according to claim 7,
wherein the first determination circuit is configured to perform contour extraction, and
wherein the second determination circuit is configured to execute one or more techniques selected from a deep neural network, a convolutional neural network, a recurrent neural network, an autoencoder, a deep Boltzmann machine, and a deep belief network.

12. The determination system according to claim 7,
wherein the first determination circuit is configured to perform contour extraction, and
wherein the event is detection of a human using the contour extraction.

13. The determination system according to claim 7,
wherein the first determination circuit is configured to perform contour extraction, and
wherein the first determination circuit performs face recognition of a human using the contour extraction.
